(19) United States
(12) Patent Application Publication
(10) Pub. No.: US 2026/0344217 A1
(43) Pub. Date: Oct. 29, 2026

(54) Display Apparatus

(71) Applicant: LG Display Co., Ltd., Seoul (KR)

(72) Inventors: Dongkyu Lee, Goyang-si (KR); Kyu-Hwang Lee, Paju-si (KR); Munchan Kang, Goyang-si (KR)

(21) Appl. No.: 19/573,424

(22) Filed: Mar. 20, 2026

(30) Foreign Application Priority Data
Apr. 29, 2025 (KR) 10-2025-0056476

(51) Int. Cl. H10K 59/131; H10K 59/80

(52) U.S. Cl. CPC H10K 59/131; H10K 59/873

(57) ABSTRACT

A display apparatus includes: a first pad area disposed in a non-display area of a first substrate; a first pad disposed on an upper surface of the first pad area and including a first pattern and a plurality of second patterns, wherein the plurality of second patterns are spaced from each other by a first spacing; a second substrate disposed on top of the first substrate and including a second pad area; and a second pad disposed on a lower surface of the second pad area and including a third pattern and a plurality of fourth patterns, wherein the plurality of fourth patterns are spaced from each other by a second spacing, wherein each of the fourth patterns is disposed in the first spacing and contacts a side surface of each of the second patterns.

### CROSS-REFERENCE TO RELATED APPLICATION

This application claims priority from Republic of Korea Patent Application No. 10-2025-0056476 filed on Apr. 29, 2025, which is hereby incorporated by reference in its entirety.

### BACKGROUND

### Technical Field

The present disclosure relates to a display apparatus.

### Description of Related Art

The contents described in this section merely provides background information on the present disclosure and does not constitute the prior art.

The display apparatus is applied to various electronic devices such as a TV, a smartphone, a laptop computer, and a tablet. To this end, research is being conducted to develop a thin, light weight, and low power consuming display apparatus.

Examples of the display apparatus include a liquid crystal display apparatus (LCD), a field emission display apparatus (FED), and an organic light-emitting display apparatus (OLED).

The display apparatus may include a display panel in which a plurality of pixels are disposed, and various electronic components for driving the display panel. Among the various electronic components, a driving circuit chip (Drive-IC) may transmit power or signals provided from a printed circuit board to the display panel to control the plurality of pixels.

Accordingly, research has been conducted on a configuration for stably transmitting the power or signals provided from the printed circuit board to the display panel.

### SUMMARY

A scheme of coupling the driving circuit chip and the display panel to each other may vary depending on a type of a substrate on which the driving circuit chip is mounted. For example, a scheme of coupling the driving circuit chip to the display panel may include a COG (Chip on glass) scheme, a COF (Chip on film) scheme, a COP (Chip on plastic) scheme, etc.

A conductive film may be used to electrically connect the driving circuit chip and the display panel to each other. In the conductive film, a plurality of conductive balls (or particles) are dispersed in an insulating material. The conductive film may be placed into between the display panel and the driving circuit chip which in turn may be bonded to each other in a thermal compression scheme. Thus, the conductive balls of the conductive film may contact both the display panel and the driving circuit chip, such that the display panel and the driving circuit chip may be electrically connected to each other.

However, in the scheme using the conductive film, a defect in which the display panel and the driving circuit chip are not electrically connected to each other may occur. In particular, as each of various electronic devices has recently been miniaturized and thinned, the sizes of various electronic components disposed in the electronic devices are also decreasing. In addition, as sizes of electrodes or contact and connection pads disposed in the electronic component are also reduced, a pitch as a spacing between the adjacent electrodes or the adjacent contact and connection pads is also reduced.

However, a short circuit may occur between the contact and connection pads spaced from each other by a fine pitch, or an open circuit in which electrical connection therebetween is not established may occur. Accordingly, a defect in which power or signals are not stably transmitted to the sub-pixels in the display panel may occur.

Accordingly, the inventors of the present disclosure have invented a display apparatus capable of stably implementing an electrical connection between a display panel and a driving circuit chip through various experiments.

A technical purpose of the present disclosure is to provide a display apparatus capable of preventing an electrical connection failure between a display panel and a driving circuit chip.

In addition, a technical purpose of the present disclosure is to provide a display apparatus capable of preventing occurrence of an alignment error in which a pad on a driving circuit chip package and a pad on a display panel are not aligned with each other in a reference alignment range when bonding the driving circuit chip package and the display panel to each other.

In addition, a technical purpose of the present disclosure is to provide a display apparatus capable of preventing a contact and connection failure between a display panel including contact and connection pads spaced from each other by a fine pitch and a driving circuit chip including contact and connection pads spaced from each other by a fine pitch from occurring.

In addition, a technical purpose of the present disclosure is to provide a display apparatus capable of preventing a defective connection between the contact and connection pads spaced from each other by a fine pitch to reduce a defection rate of a product, thereby reducing the production energy due to additional production of a product to reduce the discharge of greenhouse gas.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display apparatus according to an embodiment of the present disclosure includes: a first substrate including a display area and a non-display area disposed outside the display area; a first pad area disposed in the non-display area of the first substrate; a first pad disposed on an upper surface of the first pad area and including a first pattern and a plurality of second patterns, wherein the plurality of second patterns are arranged to be spaced from each other by a first spacing; a second substrate disposed on top of the first substrate and including a second pad area; and a second pad disposed on a lower surface of the second pad area and including a third pattern and a plurality of fourth patterns, wherein the plurality of fourth patterns are arranged to be spaced from each other by a second spacing, wherein each of the fourth patterns is disposed in the first spacing and contacts a side surface of each of the second patterns.

The display apparatus according to the embodiments of the present disclosure may be configured to have a structure in which one input pad of the display panel composed of a plurality of pad patterns and one output pad of the driving circuit chip package composed of a plurality of pad patterns are coupled to each other. Accordingly, the conductive ball may be omitted, such that there is an effect of preventing occurrence of a short circuit defect or an open circuit defect caused by the conductive ball.

Therefore, the electrical connection between the display panel and the driving circuit chip package may be stably achieved, such that the defect rate of the display apparatus may be reduced. As a result, there is an effect that production energy required for additional production of the display apparatus may be reduced and greenhouse gas emission may be reduced.

In addition, the display apparatus according to the embodiments of the present disclosure does not require the conductive ball in the bonding process between the display panel and the driving circuit chip package, such that contact and connection pads spaced from each other a finer pitch may be arranged in the highly dense manner, thereby implementing a high-resolution display apparatus.

In addition, in the display apparatus according to the present disclosure, each structure constructed to minimize the influence of misalignment during the bonding process may be disposed on each of the driving circuit chip package and the display panel. Accordingly, the occurrence of the alignment error in which each of the pads of the driving circuit chip package and the display panel is disposed at a position deviating from the reference alignment range may be prevented, thereby improving the reliability of the product.

The effects of the present disclosure are not limited to the effects mentioned above, and other effects not mentioned will be clearly understood by those skilled in the art from the following descriptions.

### BRIEF DESCRIPTION OF DRAWINGS

FIG. 1 is a plan view of a display apparatus according to embodiments of the present disclosure.

FIG. 2 is an exploded view of components illustrated in FIG. 1.

FIG. 3 is an enlarged plan view of an area I of FIG. 2.

FIG. 4 is an enlarged plan view of an area II of FIG. 2.

FIG. 5 is a cross-sectional view taken along a line III-III' of FIG. 1.

FIG. 6 is an enlarged view of an area IV of FIG. 1.

FIGS. 7 to 10 are diagrams illustrating a display apparatus according to an embodiment of the present disclosure.

FIG. 11 is a diagram illustrating a display apparatus in which first and second substrates are coupled to each other using a conductive ball.

FIGS. 12 and 13 are diagrams illustrating a display apparatus according to another embodiment of the present disclosure.

FIGS. 14 and 15 are diagrams illustrating a display apparatus according to still another embodiment of the present disclosure.

FIGS. 16 and 17 are diagrams illustrating a display apparatus according to still yet another embodiment of the present disclosure.

FIGS. 18 and 19 are diagrams illustrating a display apparatus according to still yet another embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this specification, specify the presence of the stated features, integers, operations, elements, and/or components, but do not preclude the presence or addition of one or more other features, integers, operations, elements, components, and/or portions thereof.

As used herein, the term "and/or" includes any and all combinations of one or more of associated listed items. Expression such as "at least one of" when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present "on" a second element or layer, the first element may be disposed directly on the second element or may be disposed indirectly on the second element with a third element or layer being disposed between the first and second elements or layers.

It will be understood that when an element or layer is referred to as being "connected to", or "connected to" another element or layer, it may be directly on, connected to, or connected to the other element or layer, or one or more intervening elements or layers may be present.

In addition, it will also be understood that when an element or layer is referred to as being "between" two elements or layers, it may be the only element or layer between the two elements or layers, or one or more intervening elements or layers may also be present.

Further, as used herein, when a layer, film, region, plate, or the like is disposed "on" or "on top" of another layer, film, region, plate, or the like, the former may directly contact the latter or still another layer, film, region, plate, or the like may be disposed between the former and the latter. As used herein, when a layer, film, region, plate, or the like is directly disposed "on" or "on top" of another layer, film, region, plate, or the like, the former directly contacts the latter and still another layer, film, region, plate, or the like is not disposed between the former and the latter. Further, as used herein, when a layer, film, region, plate, or the like is disposed “under” another layer, film, region, plate, or the like, the former may directly contact the latter or still another layer, film, region, plate, or the like may be disposed between the former and the latter. As used herein, when a layer, film, region, plate, or the like is directly disposed "under" another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms "first", "second", "third", and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship with each other.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In description of flow of a signal, for example, when a signal is delivered from a node A to a node B, this may include a case where the signal is transferred from the node A to the node B via another node unless a phrase 'immediately transferred' or 'directly transferred' is used.

Hereinafter, a display apparatus according to each embodiment of the present disclosure will be described with reference to the accompanying drawings.

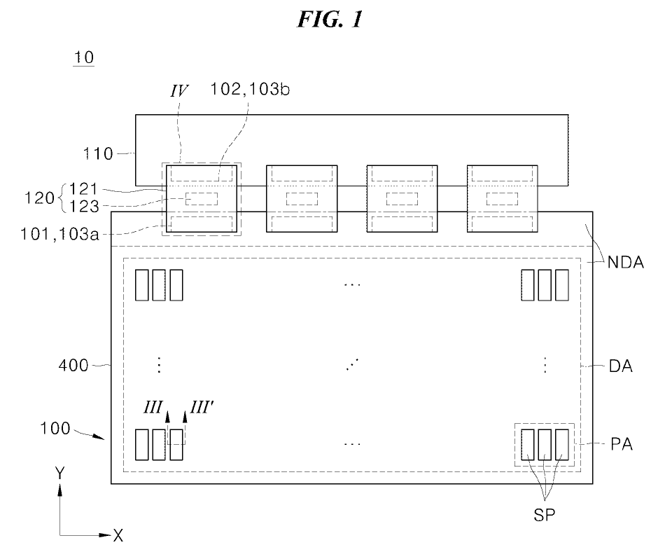

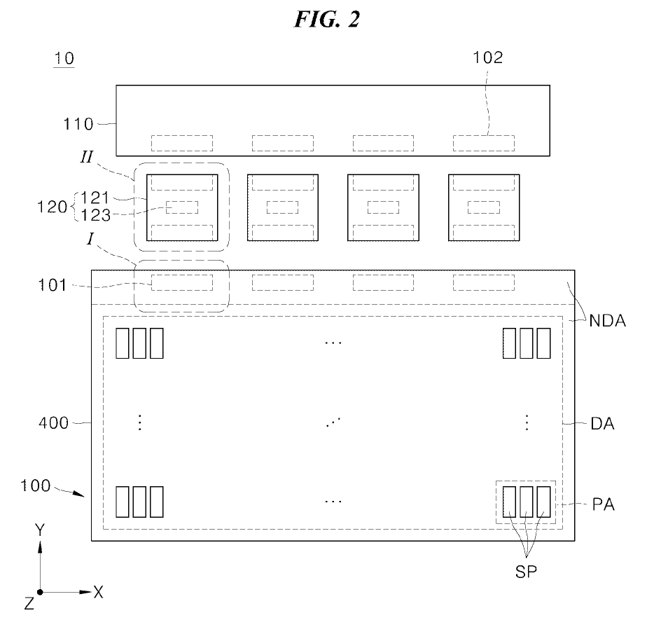

FIG. 1 is a plan view of a display apparatus according to embodiments of the present disclosure. FIG. 2 is an exploded view of components illustrated in FIG. 1.

Referring to FIGS. 1 and 2, a display apparatus 10 according to embodiments of the present disclosure may include a display panel 100, a printed circuit board 110, and a driving circuit chip package 120. The display panel 100, the printed circuit board 110, and the driving circuit chip package 120 may be electrically connected to each other. In the display apparatus 10 according to embodiments of the present disclosure, the display panel 100 and the driving circuit chip package 120 are coupled to each other in a chip on film (COF) manner. However, embodiments of the present disclosure are not limited thereto.

The display panel 100 may include a first substrate 400. The display panel 100 may include a display area DA and a non-display area NDA located outside the display area DA. The display panel 100 may include a plurality of light-emitting elements, circuit elements for driving the light-emitting elements, and a plurality of lines (not shown).

The display area DA may be an area in which an image is displayed, and the non-display area NDA may be an area in which an image is not displayed. The non-display area NDA may be located in a peripheral area or the edge area of the display panel 100. However, embodiments of the present disclosure are not limited thereto. For example, an area other than a light emission area in which light is emitted to the outside in the display area DA may be referred to as the non-display area NDA.

A plurality of pixel areas PA may be disposed in the display area DA. Each of the pixel areas PA may include a plurality of sub-pixels SP. An image may be displayed in the display area DA by applying a driving signal to the plurality of sub-pixels SP. Various lines and circuits for driving the plurality of sub-pixels SP of the display area DA may be disposed in the non-display area NDA. For example, driving circuits including a gate driving circuit and a data driving circuit may be disposed in the non-display area NDA. Several drivers for driving the display area DA may be disposed in the non-display area NDA. For example, the drivers may include a gate driver and a data driver. However, embodiments of the present disclosure are not limited thereto.

The display panel 100 may include a plurality of first pad areas 101. The plurality of first pad areas 101 may be disposed in the non-display area NDA of the display panel 100. For example, the first pad areas 101 may be arranged to be spaced apart from each other in a first direction X while being disposed at one side edge of the display panel 100. An area in which the plurality of first pad areas 101 are disposed in the non-display area NDA may be referred to as a pad area.

The printed circuit board 110 may be disposed adjacent to at least one side edge of the non-display area NDA. The printed circuit board 110 may transmit various signals or power to the display panel 100 via the driving circuit chip package 120. The printed circuit board 110 may include a flexible substrate made of a flexible material. A plurality of third pad areas 102 in which a plurality of output pads are disposed may be disposed at one side edge of the printed circuit board 110 and may be provided and may be arranged to be spaced apart from each other in the first direction X. The plurality of third pad areas 102 may correspond to the plurality of first pad areas 101, respectively.

The driving circuit chip package 120 may be disposed between the display panel 100 and the printed circuit board 110. A plurality of driving circuit chip packages 120 may be provided and may be arranged to be spaced apart from each other in the first direction X. Each of the driving circuit chip packages 120 may be connected to and disposed between each of the plurality of third pad areas 102 and each of the plurality of first pad areas 101.

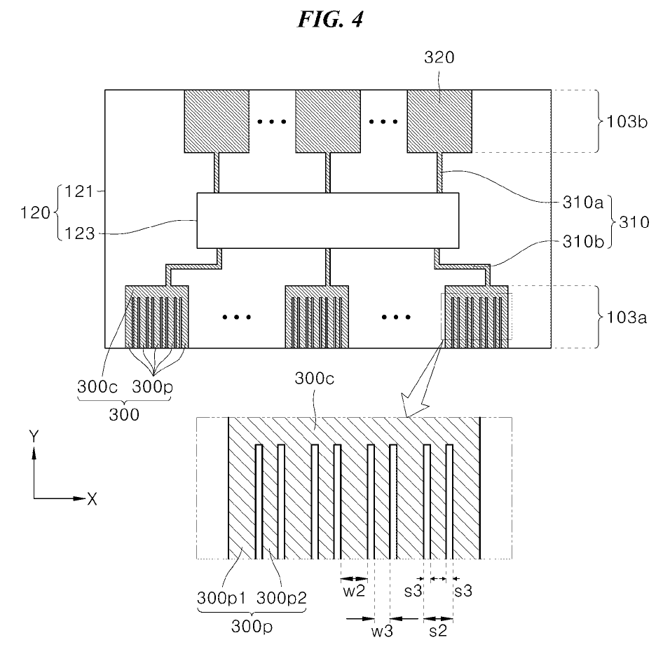

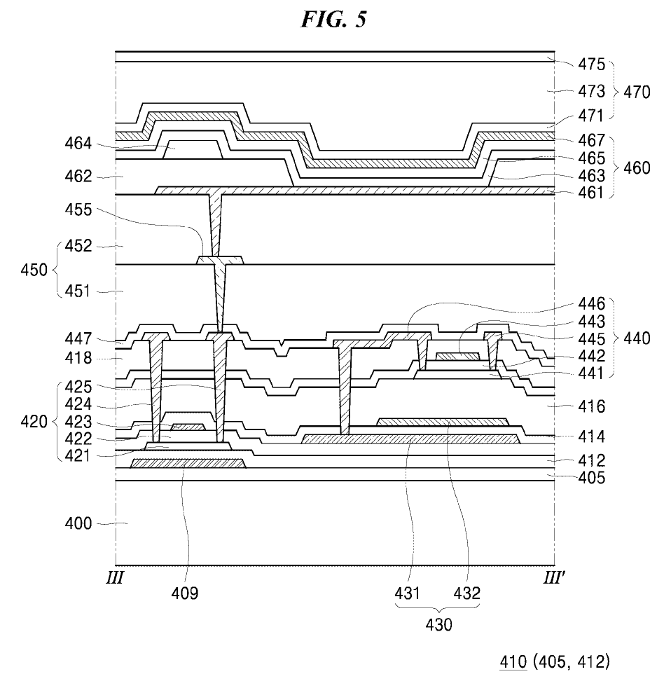

Each of the driving circuit chip packages 120 may include a second substrate 121, a driving circuit chip 123, a plurality of second pad areas 103, and a plurality of lines (not shown). The second substrate 121 may be embodied as a plastic film having flexibility. At least one driving circuit chip 123 may be included in one driving circuit chip package 120. The plurality of second pad areas 103 may include first areas 103a and second areas 103b. The first areas 103a may be arranged to be spaced apart from each other in the first direction X while being disposed at one of both opposing side edges in a second direction Y intersecting the first direction X of the driving circuit chip package 120. The second areas 103b may be arranged to be spaced apart from each other in the first direction X while being disposed at the other of both opposing side edges in a second direction Y intersecting the first direction X of the driving circuit chip package 120. A plurality of pads may be included in one second pad area 103. That is, the plurality of pads may be included in each of the first areas 103a. The plurality of pads may be included in each of the second areas 103b. The plurality of pads may include, for example, a plurality of output pads in the first area and a plurality of input pads in the second area. This will be described later in FIG. 4.

The driving circuit chip package 120 may provide power or a signal supplied from the printed circuit board 110 to the light-emitting element of the display panel 100 and circuit elements for driving the light-emitting element of the display panel 100. For example, the power or signal may include a high potential voltage, a low potential voltage, a scan signal, a data signal, etc.

One side in the second direction Y of the driving circuit chip package 120 may be coupled to the display panel 100, and the other side in the second direction Y thereof may be coupled to the printed circuit board 110. The first areas 103a and the second areas 103b may be included in the plurality of second pad areas 103 of the driving circuit chip package 120. The first area 103a may be disposed at a position overlapping the first pad area 101 of the display panel 100 in the vertical direction. The second area 103b may be disposed at a position overlapping the third pad area 102 of the printed circuit board 110 in the vertical direction. In an example, the display panel 100 may include a bendable area in which a partial area of the non-display area NDA is bent. When the bendable area of the display panel 100 is bent, the printed circuit board 110 and the driving circuit chip package 120 may be disposed on a rear surface of the display area DA of the display panel 100. The bendable area may refer to an area located between the display panel 100 and the driving circuit chip package 120. For example, the bendable area may be a portion of an area of the non-display area NDA of the display panel 100 that does not overlap the driving circuit chip package 120 in the vertical direction.

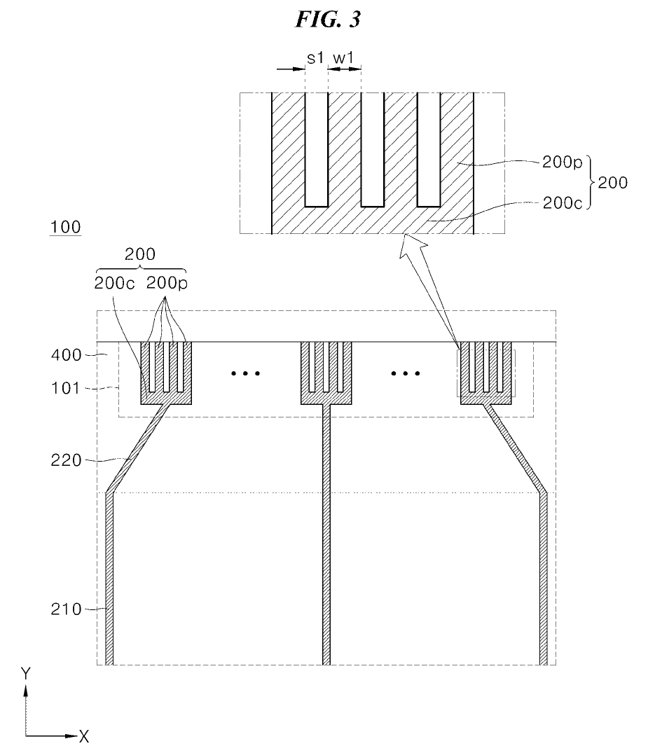

FIG. 3 is an enlarged plan view of an area I of FIG. 2. FIG. 4 is an enlarged plan view of an area II of FIG. 2. For example, FIG. 3 illustrates one first pad area 101 of the display panel 100. FIG. 4 is an enlarged view of one driving circuit chip package 120.

Referring to FIG. 3, the first pad area 101 may include a plurality of first pads 200 and a plurality of first lines 210 disposed on the first substrate 400 of the display panel 100. The plurality of first pads 200 may be arranged to be spaced apart from each other in the first direction X. The plurality of first lines 210 may be arranged to be spaced apart from each other in the first direction X.

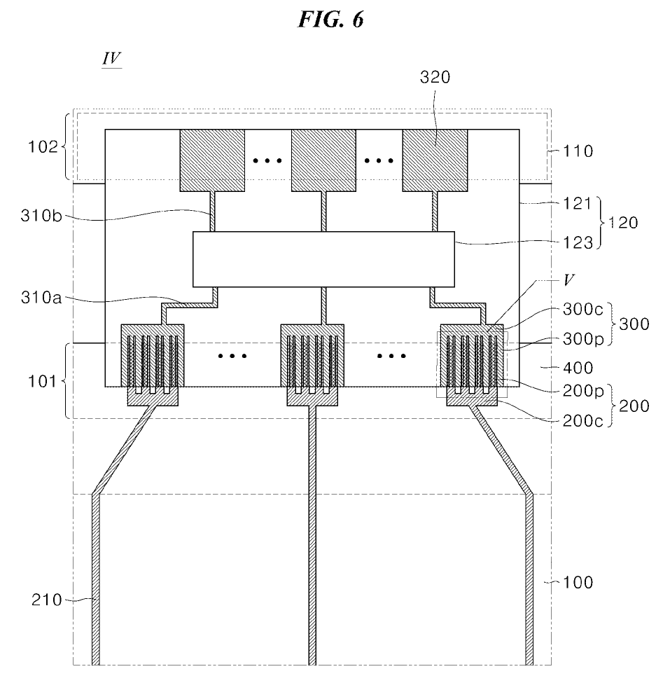

Each first line 210 may be connected to each first pad 200. The plurality of first pads 200 may be input pads. For example, the plurality of first pads 200 may be the input pads to which signals provided from the driving circuit chip package 120 are input. In an example, one surface of the first substrate 400 on which the plurality of first pads 200 are disposed may be a connection surface coupled to the driving circuit chip package. The plurality of first pads 200 may be disposed in the first pad area 101 disposed on one side edge in the second direction Y of the first substrate 400. The plurality of first pads 200 may be arranged to be spaced apart from each other along the first direction X of the first substrate 400. The first direction X may also be referred to as an X-axis direction, a longitudinal direction or a row direction. Each of the plurality of first pads 200 may be connected to a second pad as an output pad of the driving circuit chip. This will be described later in FIG. 6.

One first pad 200 may include first pad patterns 200c and 200p. The first pad patterns 200c and 200p may include a first pattern 200c and a plurality of second patterns 200p. The first pattern 200c and the plurality of second patterns 200p may be integrally formed with each other. For example, the plurality of second patterns 200p may have a shape branching off from the first pattern 200c and extending therefrom. The first pattern 200c may be formed in a line or rod shape extending along the first direction X of the first substrate 400. Each of the plurality of second patterns 200p may have a shape branched from the first pattern 200c and extending in the second direction Y intersecting the first direction X. For example, the first pad 200 may have a comb-like structure.

Referring to the enlarged view of one first pad 200, each of the second patterns 200p may have a first width w1 in the first direction X, and neighboring second patterns 200p may be spaced apart from each other by a first spacing s1 in the first direction X. For example, the neighboring second patterns 200p may be arranged to be spaced apart from each other in the first direction X of the first substrate 400. The respective first widths w1 of the second patterns 200p may be equal to each other. One of the plurality of first lines 210 may be connected to one first pattern 200c. The plurality of first lines 210 may be electrically connected to the plurality of light-emitting elements and the circuit elements of the display area DA, respectively.

The signal supplied from the printed circuit board 110 (see FIG. 1) may be supplied to each of the plurality of second patterns 200p of each of the plurality of first pads 200 of the display panel 100. The plurality of second patterns 200p and the first patterns 200c may be integrally formed with each other so that the signals respectively supplied from the second patterns 200p to the sub-pixel SP may be the same as each other. Accordingly, the signal supplied from the printed circuit board 110 may be divided into the same signals respectively flowing through the second patterns 200p, and then the same signals may be merged into one signal again in the first pattern 200c. The merged signal may be transmitted to the sub-pixel SP via the first line 210 connected to the first pattern 200c. In this case, each of the same signals respectively flowing through the plurality of second patterns 200p may be the same as the signal flowing through the first pattern 200c.

The signal provided from the printed circuit board 110 (see FIG. 1) may be transmitted to the plurality of first pads 200 of the display panel 100 via the pads 300 and 320 of the driving circuit chip package 120 of FIG. 4.

Referring to FIG. 4, the driving circuit chip package 120 may include the second substrate 121, the pads 300 and 320 disposed on a surface of the second substrate 121, and a plurality of second lines 310. The pads 300 and 320 of the driving circuit chip package 120 may include a plurality of second pads 300 and a plurality of third pads 320. The plurality of second pads 300 may be output pads for outputting signals to the display panel 100. The plurality of third pads 320 may be input pads to which signals or power provided from the printed circuit board 110 are input. In an example, one surface of the second substrate 121 on which the pads 300 and 320 are disposed may be a connection surface coupled to each of the display panel 100 and the printed circuit board 110.

The plurality of second pads 300 may be disposed in the first area 103a of the second pad area 103 disposed on one side edge in the second direction Y of the second substrate 121. The plurality of second pads 300 may be arranged to be spaced apart from each other along the first direction X of the second substrate 121. The first direction X may also be referred to as an X-axis direction, a longitudinal direction, or a row direction. The plurality of second pads 300 may be respectively connected to the plurality of first pads 200 of the display panel 100. This will be described later in FIG. 6.

One second pad 300 may include second pad patterns 300c and 300p. The second pad patterns 300c and 300p may include a third pattern 300c and a plurality of fourth patterns 300p. The third pattern 300c and the plurality of fourth patterns 300p may be integrally formed with each other. For example, each of the plurality of fourth patterns 300p may have a shape branching off from the third pattern 300c and extending therefrom. The third pattern 300c may be formed in a line or rod shape extending along the first direction X of the second substrate 121. Each of the plurality of fourth patterns 300p may have a shape branching from the third pattern 300c and extending in the second direction Y intersecting the first direction X. For example, the second pad 300 may have a comb-like structure.

Referring to an enlarged view of one second pad 300, each of the fourth patterns 300p may include a first fin pattern 300p1 and a second fin pattern 300p2. The first fin patterns 300p1 and the second fin patterns 300p2 may be alternately arranged with each other. For example, each second fin pattern 300p2 may be disposed between adjacent ones of the first fin patterns 300p1. The first fin pattern 300p1 may constitute each of both opposing ends in the first direction X of one second pad 300.

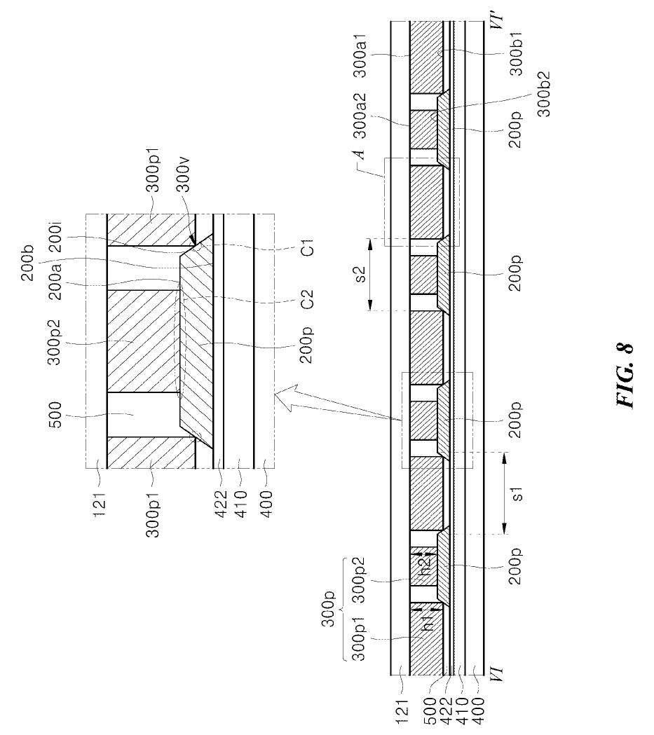

The first fin pattern 300p1 and the second fin pattern 300p2 may have different widths w2 and w3. For example, the first widthw2 in the first direction X of the first fin pattern 300p1 may be greater than the second width w3 in the first direction X of the second fin pattern 300p2. The neighboring first fin patterns 300p1 may be arranged to be spaced apart from each other by a second spacing s2. The second fin pattern 300p2 branched from the third pattern 300c may be disposed in an area of the second spacing s2. For example, the first fin pattern 300p1 and the second fin pattern 300p2 may be spaced apart from each other by a third spacings3. The first fin pattern 300p1 and the second fin pattern 300p2 may have different vertical lengths. This will be described later in FIG. 8.

The plurality of third pads 320 may be disposed in the second area 103b opposite to the first area 103a in the second direction Y. The second area 103b may be located on the other side edge in the second direction Y of the second substrate 121. The plurality of third pads 320 may be arranged to be spaced apart from each other along the first direction X of the second substrate 121. The plurality of third pads 320 may be connected to the printed circuit board 110. The shape of each of the plurality of third pads 320 may be different from the shape of each of the plurality of second pads 300. For example, each of the plurality of third pads 320 may be formed as a polygonal plate in a plan view. For example, in the plan view, one third pad 320 may have a rectangular shape having a short side extending in the first direction X and a long side extending in the second direction Y.

The driving circuit chip 123 may be disposed between and connected to the plurality of second pads 300 and the plurality of third pads 320 in the second direction Y. The plurality of second pads 300 and the driving circuit chip 123 may be electrically connected to each other via the plurality of second lines 310, respectively, while the plurality of third pads 320 and the driving circuit chip 123 may be electrically connected to each other via the plurality of second lines 310, respectively. For example, first sub-lines 310a of the plurality of second lines 310 may electrically connect the plurality of third pads 320 and the driving circuit chip 123 to each other, respectively. Second sub-lines 310b of the plurality of second lines 310 may electrically connect the plurality of second pads 300 and the driving circuit chip 123 to each other, respectively.

For example, the signal supplied from the printed circuit board 110 (see FIG. 1) may be transmitted to the driving circuit chip 123 via the plurality of third pads 320 and the first sub-lines 310a. The driving circuit chip 123 may convert the supplied signal and provide the converted signal to the display panel 100 via the second sub-lines 310b and the plurality of second pads 300.

The signal may be supplied to the third pattern 300c of each of the plurality of second pads 300 and then may be divided into the same signals respectively flowing through the plurality of fourth patterns 300p. Then, the divided same signals may be supplied to the display panel 100. In this case, the signal supplied to the third pattern 300c and each of the divided same signals respectively flowing through the plurality of fourth patterns 300p may be the same signal. In an example, the signal supplied toward the display panel 100 via the plurality of second pads 300 may be transmitted to a thin-film transistor TFT in the display panel 100, and an operation of each sub-pixel SP may be controlled based on the signal passing through the thin-film transistor TFT.

The first substrate 400 may include a plastic film or glass. When the first substrate 400 is embodied as a plastic film, a stack of multiple layers made of an insulating material may be disposed on the first substrate. A first buffer layer 405 may be disposed on the first substrate 400. The first buffer layer 405 may cover a surface of the first substrate 400. The first buffer layer 405 may reduce or prevent penetration of moisture, oxygen, or impurities through the first substrate 400. The first buffer layer 405 may have a single layer structure or a multilayer structure made of an inorganic insulating material such as silicon oxide (SiOx) or silicon nitride (SiNx). The first buffer layer 405 may entirely cover the first substrate 400. For example, the first buffer layer 405 may extend into the first pad area 101 (see FIG. 2).

A light shielding layer 409 may be disposed on the first buffer layer 405. The light shielding layer 409 may prevent the external light from being incident on the first transistor 220. To this end, an opaque metal material may be included in the light shielding layer 409. A second buffer layer 412 may be disposed on the light shielding layer 409. The second buffer layer 412 may protect the first transistor 220 from moisture, oxygen, or impurities. The second buffer layer 412 may have a single layer structure or a multilayer structure made of an inorganic insulating material such as silicon oxide (SiOx) or silicon nitride (SiNx). However, embodiments of the present disclosure are not limited thereto. The second buffer layer 412 may entirely cover the first substrate 400. For example, the second buffer layer 412 may extend into the first pad area 101 (see FIG. 2) that belongs to the non-display area NDA. The first buffer layer 405 and the second buffer layer 412 may vertically overlap each other in the first pad area 101. A stack of the first buffer layer 405 and the second buffer layer 412 in the first pad area 101 may be referred to as a multi-buffer layer 410.

The first transistor 420 may be disposed on the second buffer layer 412. The first transistor 420 may include a first semiconductor layer 421, a first gate insulating layer 422, a first gate electrode 423, a first source electrode 424, and a first drain electrode 425. In an example, the first transistor 420 may be a driving transistor electrically connected to the light-emitting element 460. An area of the first semiconductor layer 421 overlapping the first gate electrode 423 in the vertical direction may be a channel area. The source/drain areas may be disposed on both opposing sides of the channel area, respectively. The first semiconductor layer 421 may be disposed to overlap the light shielding layer 409 in the vertical direction. The light shielding layer 409 may prevent the external light from being incident on the first semiconductor layer 421.

The first gate insulating layer 422 may be disposed between the first semiconductor layer 421 and the first gate electrode 423. The first gate insulating layer 422 may extend outwardly while covering the first semiconductor layer 421. In an example, the first gate insulating layer 422 may extend into the first pad area 101 (see FIG. 2).

The first gate electrode 423 may be disposed on the first gate insulating layer 422. A first interlayer insulating layer 414 may be disposed on the first gate electrode 423. The first gate insulating layer 422 or the first interlayer insulating layer 414 may have a single layer structure or a multilayer structure made of an inorganic insulating material such as silicon oxide (SiOx) or silicon nitride (SiNx). The first source electrode 424 and the first drain electrode 425 may be in contact with and electrically connected to the first semiconductor layer 421.

A storage capacitor 430 may include a first storage electrode 431 and a second storage electrode 432. For example, the first storage electrode 431 may be located in the same layer as a layer of the first gate electrode 423 and may be made of the same material as that of the first gate electrode 423. The first storage electrode 431 may be disposed on the first gate insulating layer 422 and at a position spaced apart from the first gate electrode 423. The second storage electrode 432 may be disposed on the first interlayer insulating layer 414 so as to overlap the first storage electrode 431 in the vertical direction.

A second interlayer insulating layer 416 may be disposed on the second storage electrode 432. The second interlayer insulating layer 416 may have a single layer structure or a multilayer structure made of an inorganic insulating material such as silicon oxide (SiOx) or silicon nitride (SiNx).

A second transistor 440 may be disposed on the second interlayer insulating layer 416 and in a position spaced apart from the first transistor 420 in the first or second direction. The second transistor 440 may be electrically connected to the first transistor 420. For example, the second transistor 440 may include a second semiconductor layer 441, a second gate insulating layer 442, a second gate electrode 443, a second source electrode 445, and a second drain electrode 446. For example, the second transistor 440 may act as a switching transistor. The second semiconductor layer 441 may include a channel area and source/drain areas. An area of the second semiconductor layer 441 overlapping the second gate electrode 443 in the vertical direction may be a channel area. The source/drain areas may be disposed on both opposing sides of the channel area, respectively. In an example, the second semiconductor layer 441 may be disposed to overlap the storage capacitor 430 in the vertical direction. Accordingly, the storage capacitor 430 may prevent the external light from the outside out of the first substrate 400 from being incident on the second semiconductor layer 441. Accordingly, a change in electrical characteristics such as a threshold voltage of the second transistor 440 due to the external light may be prevented.

The second gate insulating layer 442 may be disposed between the second semiconductor layer 441 and the second gate electrode 443. The second gate insulating layer 442 may have a single layer structure or a multilayer structure made of an inorganic insulating material such as silicon oxide (SiOx) or silicon nitride (SiNx). The first gate electrode 423 or the second gate electrode 443 may have a single layer structure or a multilayer structure made of one of molybdenum (Mo), aluminum (Al), chromium (Cr), gold (Au), titanium (Ti), nickel (Ni), neodymium (Nd), and copper (Cu), or an alloy thereof. However, the material thereof is not limited thereto.

A third interlayer insulating layer 418 may be disposed on the second gate electrode 443. The third interlayer insulating layer 418 may include an inorganic insulating material. For example, silicon oxide, silicon nitride, and silicon oxynitride may be included in the third interlayer insulating layer 418.

The first source electrode 424, the first drain electrode 425, the second source electrode 445, and the second drain electrode 446 may be disposed on the third interlayer insulating layer 418. The first source electrode 424 and the first drain electrode 425 may extend through the second interlayer insulating layer 418, the second gate insulating layer 442, the second interlayer insulating layer 416, the first interlayer insulating layer 414, and the first gate insulating layer 422 so as to be in direct contact with and connected to the source/drain areas of the first semiconductor layer 421, respectively.

The second source electrode 445 and the second drain electrode 446 may extend through the second interlayer insulating layer 418 and the second gate insulating layer 442 so as to be in direct contact with and connected to the source/drain areas of the second semiconductor layer 441, respectively. The second drain electrode 446 of the second transistor 440 may be electrically connected to the storage capacitor 430. For example, a portion of the second drain electrode 446 may extend through the second interlayer insulating layer 418, the second gate insulating layer 442, the second interlayer insulating layer 416, and the first interlayer insulating layer 414 so as to be in direct contact with and connected to the first storage electrode 431 of the storage capacitor 430.

Each of the first source electrode 424, the first drain electrode 425, the second source electrode 445, or the second drain electrode 446 may have a single layer structure or a multilayer structure made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In an example, the first source electrode 424, the first drain electrode 425, the second source electrode 445, or the second drain electrode 446 may have a stacked structure of titanium layer/aluminum layer/titanium layer (Ti/Al/Ti).

A passivation layer 447 may be disposed on the first source electrode 424, the first drain electrode 425, the second source electrode 445, or the second drain electrode 446. The passivation layer 447 may include an inorganic insulating material such as silicon oxide, silicon nitride, and silicon oxynitride. The passivation layer 447 may protect the pixel driving circuit disposed thereunder.

A planarization layer 450 may be disposed on the passivation layer 447. The planarization layer 450 may planarize a step caused due to the pixel driving circuit disposed thereunder. The planarization layer 450 may have a multilayer structure. The planarization layer 450 may include a first planarization layer 451 and a second planarization layer 452. For example, the planarization layer 450 may include an organic insulating material such as polyimide or acrylic resin. The planarization layer 450 is illustrated as having a structure in which the first planarization layer 451 and the second planarization layer 452 are vertically stacked in the drawing. However, embodiments of the present disclosure are not limited thereto. The planarization layer 450 may have a multilayer structure further including a third planarization layer (not shown).

A pixel contact electrode 455 may be disposed on the first planarization layer 450. The pixel contact electrode 455 may extend through the first planarization layer 450 and the passivation layer 447 so as to directly contact the first drain electrode 425 of the first transistor 420.

The light-emitting element 460 may be formed on the planarization layer 450. For example, the light-emitting element 460 may be disposed on the second planarization layer 452. The light-emitting element 460 may include a first electrode 461, a light-emitting layer 463, a second electrode 465, and a capping layer 467.

The light-emitting element 460 may be electrically connected to the pixel driving circuit via the first electrode 461. For example, the first electrode 461 may extend through the second planarization layer 452 so as to directly contact the pixel contact electrode 455. Accordingly, the first electrode 461 may be electrically connected to the first transistor 420 via the pixel contact electrode 455. The pixel contact electrode 455 may include a conductive material. For example, the pixel contact electrode 455 may include a metal material such as aluminum (Al), chromium (Cr), copper (Cu), titanium (Ti), molybdenum (Mo), and tungsten (W). For example, the pixel contact electrode 455 may have a multilayer structure of titanium layer/aluminum layer/titanium layer (Ti/Al/Ti).

The first electrode 461 may include a transparent conductive layer. For example, the first electrode 461 may include ITO (Indium Tin Oxide) or IZO (Indium Zinc Oxide). The first electrode 461 may also be referred to as an anode electrode or a pixel electrode.

A bank 462 may be disposed on the first electrode 461. The bank 462 may be disposed to cover an edge of the first electrode 461. A portion of the bank 462 may extend so as to be disposed on the second planarization layer 452. A portion of an upper surface of the first electrode 461 not covered with the bank 462 as to be exposed may act as the light emission area. The bank 462 may be made of an organic insulating material. The bank 462 may include, for example, photosensitive polyimide, photoacryl, or benzocyclobutene (BCB). In an example, the bank 462 may include a black material, a light blocking material, or a light absorbing material. The bank 462 may include a material that absorbs light in a specific wavelength range. The bank 462 may have a structure in which at least two color filters of different colors among a red color filter, a green color filter, and a blue color filter are stacked.

A spacer 464 may be disposed on the bank 462. The spacer 464 may be disposed to prevent damage to the bank 462 and the first electrode 461 during the process. The spacer 464 may be made of the same material as that of the bank 462.

The light-emitting layer 463 may be disposed on the first electrode 461. The light-emitting layer 463 may include a hole transport layer (HTL), an organic light-emitting layer (EML), an electron transport layer (ETL), a hole blocking layer (HBL), a hole injection layer (HIL), an electron blocking layer (EBL), and an electron injecting layer (EIL). The light-emitting layer 463 may have a multilayer structure.

The second electrode 465 may be disposed on the light-emitting layer 463. The second electrode 465 may be commonly connected to the light-emitting layers 463 respectively formed in all sub-pixels. Accordingly, the second electrode 465 may also be referred to as a cathode electrode or a common electrode. The second electrode 465 may include a transflective conductive material. For example, the second electrode 465 may include a metal material such as magnesium (Mg), silver (Ag), or an alloy (Ag-Mg) of silver (Ag) and magnesium (Mg).

The capping layer 467 may be disposed on the second electrode 465. The capping layer 467 may correct optical characteristics by preventing light generated from the light-emitting layer 463 from being lost.

An encapsulation portion 470 may be disposed on the light-emitting element 460. The encapsulation portion 470 may protect the light-emitting element 460 from external oxygen or moisture. The encapsulation portion 470 may include a multi-layered structure in which a first encapsulation layer 471, a second encapsulation layer 473, and a third encapsulation layer 475 are stacked. The second encapsulation layer 472 may be disposed between the first encapsulation layer 471 and the third encapsulation layer 475. An inorganic insulating material may be included in each of the first encapsulation layer 471 and the third encapsulation layer 475, and an organic insulating material may be included in the second encapsulation layer 472.

Although not shown in the drawings, when the display apparatus performs a touch operation, the touch unit may be disposed on the encapsulation portion 470. The touch unit may include a touch sensor array and a touch sensor array protective layer.

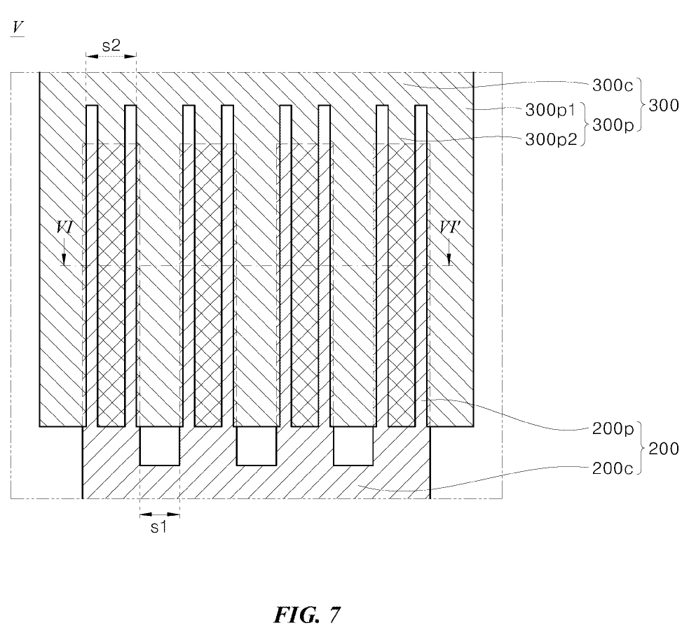

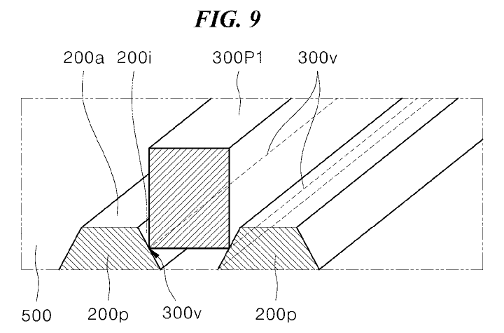

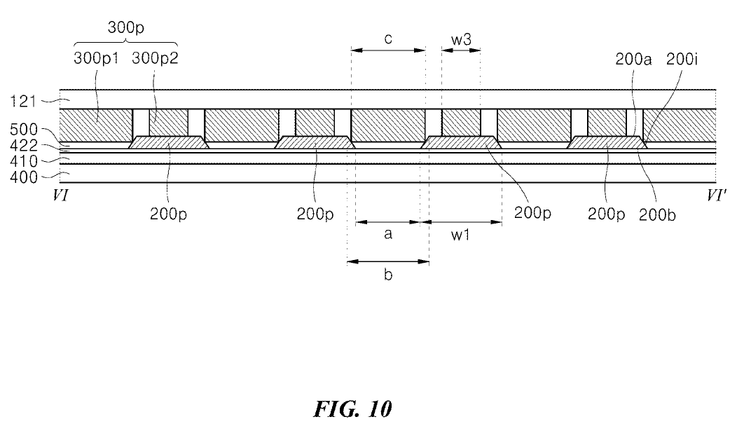

FIG. 6 is an enlarged view of an area IV of FIG. 1. FIGS. 7 - 10 are diagrams illustrating a display apparatus according to an embodiment of the present disclosure. For example, FIG. 6 is an enlarged view of a portion where a display panel and a printed circuit board are coupled to one driving circuit chip package. FIG. 7 is an enlarged view of an area V of FIG. 6. FIG. 8 is a diagram illustrating a cross-section of a line VI-VI' of FIG. 7 according to an embodiment of the present disclosure. FIG. 9 is an enlarged perspective view of a portion A of FIG. 7. FIG. 10 is a cross-sectional view illustrating a size of a width in the first direction X of each of the second pattern and the fourth pattern when the second pattern and the fourth pattern are connected to each other.

Referring to FIG. 6, the plurality of third pads 320 disposed on the other side edge in the second direction Y of the second substrate 121 of each of the driving circuit chip packages 120 may be disposed to overlap the third pad area 102 of the printed circuit board 110 in the vertical direction and may be electrically connected to the third pad area 102. The plurality of second pads 300 disposed on the one side edge in the second direction Y of the second substrate 121 of each of the driving circuit chip packages 120 may be opposite to the plurality of third pads 320 in the second direction Y and may be disposed to respectively overlap the plurality of first pads 200 in the first pad area 101 of the display panel 100 in the vertical direction and may be electrically connected to the plurality of first pads 200, respectively. For example, the printed circuit board 320 may be electrically connected to the driving circuit chip 123 via the plurality of third pads 320 and the second sub-lines 310b. The driving circuit chip 123 may be electrically connected to the first pads 200 of the display panel 100 respectively overlapping the plurality of second pads 300 in the vertical direction via the first sub-line 310a, and thus may be electrically connected to the display area DA via the plurality of first lines 210.

The plurality of second pads 300 of the driving circuit chip package 120 and the plurality of first pads 200 of the display panel 100 may be respectively and electrically connected to each other in a direct contact scheme. Hereinafter, a connection between one second pad 300 of the driving circuit chip package 120 and one first pad 200 of the display panel 100 will be described by way of example.

Referring to FIGS. 7 and 8, the second pad 300 of the driving circuit chip package 120 and the first pad 200 of the display panel 100 may be electrically connected to each other. For example, the first pad 200 and the second pad 300 may be disposed to overlap each other in the vertical direction. For example, in the plan view, the second pattern 200p of the first pad 200 may be disposed in an area corresponding to the second spacing s2 between adjacent ones of the first fin patterns 300p1 of the plurality of fourth patterns 300p of the second pad 300. In addition, in the plan view, each of the first fin patterns 300p1 of the plurality of fourth patterns 300p of the second pad 300 may be disposed in an area corresponding to the first spacing s1 between the neighboring second patterns 200p of the first pad 200.

The first fin pattern 300p1 of the second pad 300 may be disposed outwardly of the second pattern 200p constituting each of both opposing ends in the first direction X of the first pad 200. To this end, the number of the first fin patterns 300P1 of the fourth patterns 300p of the second pad 300 may be greater than the number of the second patterns 200p of the first pad 200 by at least one.

The first fin pattern 300p1 of the second pad 300 may be partially inserted into the area corresponding to the first spacing s1 disposed between adjacent ones of the second patterns 200p of the first pad 200. Referring to FIG. 8, the first fin pattern 300p1 and the second fin pattern 300p2 of the second pad 300 may have different vertical lengths h1 and h2. In this regard, the vertical length may refer to a dimension in a direction perpendicular to the plane defined by the first and second directions X and Y. For example, the first fin pattern 300p1 may have a first vertical length h1, and the second fin pattern 300p2 may have a second vertical length h2 smaller than the first vertical lengthh1. Accordingly, the second pattern 200p of the first pad 200 may be in contact with the second fin pattern 300p2 of the second pad 300 in an area corresponding to the second spacing s2. For example, an upper surface of the second pattern 200p may be in contact with a bottom surface of the second fin pattern 300p2.

The multi-buffer layer 410 may be disposed on the first substrate 400 and in the first pad area 101 (see FIG. 6) of the display panel 100. The multi-buffer layer 410 may have a stacked structure of the first buffer layer 405 and the second buffer layer 412 disposed on the display area DA of the first substrate. The first gate insulating layer 422 may be disposed on the multi-buffer layer 410. The first gate insulating layer 422 may be referred to as a protective layer. The first pad 200 may be disposed on the first gate insulating layer 422. The first pad 200 may be made of the same material as that of the first gate electrode 423 of the display area DA and be formed in the same process as a process for forming the first gate electrode 423 of the display area DA. The second pad 300 disposed on the second substrate 121 of the driving circuit chip package 120 may include a metal material including copper (Cu).

A filling layer 500 may be disposed between the first gate insulating layer 422 of the display panel 100 and the second substrate 121 of the driving circuit chip package 120. Each of the first fin patterns 300p1 of the plurality of fourth patterns 300p of the second pad 300 may extend through the filling layer 500 to be in direct contact with and coupled to the second patterns 200p of the first pad 200. The filling layer 500 may be made of an insulating material. For example, the filling layer 500 may not include a material having conductivity such as a conductive ball (or particle) and may be made only of an insulating material. For example, resin may be included in the filling layer 500.

Each of the plurality of second patterns 200p of the first pad 200 may have a first surface 200a and a second surface 200b opposite to each other in the vertical direction. In this regard, a width in the first direction X of the first surface 200a and a width in the first direction X of the second surface 200b may be different from each other. The first surface 200a may be spaced from the first gate insulating layer 422, and the second surface 200b may be opposite to the first surface 200a. The first surface 200a may be in contact with the second fin pattern 300p2 of the second pad 300. For example, the second pattern 200p may have a tapered shape whose a width in the first direction X increases as the second pattern 200p extends from the first surface 200a to the second surface 200b. Accordingly, the second pattern 200p may have a trapezoidal shape in the cross-sectional view. The second pattern 200p may include an inclined sided surface 200i having a slope from the first surface 200a to the second surface 200b.

The first fin pattern 300p1 of the fourth patterns 300p of the second pad 300 may have a first surface 300a1 and a second surface 300b1 opposite to each other in the vertical direction. In this regard, a width in the first direction X of the first surface 300a1 and a width in the first direction X of the second surface 300b1 may be equal to each other. In this regard, the first surface 300a1 of the first fin pattern 300p1 may be a surface in contact with the second substrate 121, and the second surface 300b1 thereof may be a surface facing the first gate insulating layer 422. Accordingly, each of the first fin patterns 300p1 of the second pads 300 may have a rectangular shape in the cross-sectional view. However, embodiments of the present disclosure are not limited thereto. In addition, the second fin pattern 300p2 of the fourth patterns 300p may have a first surface 300a2 and a second surface 300b2 opposite to each other which may have the same width in the first direction. In this regard, the first surface 300a2 of the second fin pattern 300p2 may be a surface in contact with the second substrate 121, and the second surface 300b2 may be a surface in contact with the first surface 200a of the second pattern 200p of the first pad 200. Accordingly, the second fin pattern 300p2 may have a rectangular shape in the cross-sectional view. However, embodiments of the present disclosure are not limited thereto. The width in the first direction X of the second fin pattern 300p2 may be smaller than the width in the first direction X of the second pattern 200p such that a portion of the second fin pattern 300p2 non-overlaps the second pattern 200p of the first pad 300 in the vertical direction is absent. Accordingly, the width in the first direction X of the second fin pattern 300p2 is smaller than the width in the first direction X of the first fin pattern 300p1.

An angle of each corner of the first fin pattern 300p1 of the second pad 300 may not be greater than 90 degrees. Therefore, each corner 300v of the first fin pattern 300p1 may be sharp enough to extend through the filling layer 500 covering the inclined side surface 200i of the second pattern 200p. Accordingly, as shown in the enlarged view of the partial area of FIG. 8, each corner (or pointed end) 300v of the first fin pattern 300p1 may extend through the filling layer 500 in the area 'C1' so as to directly contact the inclined side surface 200i of the second pattern 200p. Accordingly, the first pad 200 of the display panel 100 and the second pad 300 of the driving circuit chip package 120 may be electrically connected to each other in a direct contact manner.

The second fin pattern 300p2 of the second pad 300 may overlap with the first surface 200a of the second pattern 200p of the first pad 200 in the vertical direction. When the pressure is applied such that the display panel 100 and the driving circuit chip package 120 are coupled to each other, the second surface 300b2 of the second fin pattern 300p2 may extend through the filling layer 500. Accordingly, the second surface 300b2 of the second fin pattern 300p2 and the first surface 200a of the second pattern 200p may be electrically connected to each other in a directly contacting manner with each other in the area 'C2'. Accordingly, the fourth pattern 300p of the driving circuit chip package 120 including the first fin pattern 300p1 and the second fin pattern 300p2 may be in direct contact with not only the inclined side surface 200i of the second pattern 200p but also the first surface 200a thereof to increase the contact area, and thus may be stably electrically connected to the second pattern 200p.

Referring to FIG. 9, at least the first fin pattern 300p1 of the fourth pattern 300p of the driving circuit chip package 120 may extend along the longitudinal direction (the second direction Y) of the second pattern 200p of the first pad 200 of the display panel 100. Accordingly, each corner 300v of the first fin pattern 300p1 may be in surface-contact with the inclined side surfaces 200i of the second patterns 200p while extending in the longitudinal direction thereof.

In the display apparatus according to an embodiment of the present disclosure, instead of using a point contact type conductive ball, the second pattern 200p and the first fin pattern 300p1 may be electrically connected to each other in the line-contact manner and the second fin pattern 300p2 and the second pattern 200p may be electrically connected to each other in the surface-contact manner, thereby reliably electrically connecting the driving circuit chip 123 and the display panel 100 to each other. Accordingly, the contact and connection area between the second pattern 200p and the fourth pattern 300p may be increased, compared to that in the point contact manner. Therefore, the contact resistance between the second pattern 200p and the fourth pattern 300p is reduced, such that the electrical conductivity may be improved.

The first fin pattern 300p1 of the fourth pattern 300p of the driving circuit chip package 120 is partially inserted into the area corresponding to the first spacing s1 between the second patterns 200p adjacent to each other of the display panel 100 so as to be in contact with the respective inclined side surfaces 200i facing each other of the second patterns200p adjacent to each other. In this end, the width in the first direction X of the first fin pattern 300p1 of the driving circuit chip package 120 may be smaller than the first spacing s1 in the first direction X between the second patterns 200p adjacent to each other of the display panel 100.

Referring to FIGS. 8 and 10, a width between respective side ends facing each other of the first surfaces 200a of adjacent second patterns 200p may be a first width “b”. A width between respective side ends of the inclined side surfaces 200i facing each other of the adjacent second patterns 200p may be a second width “a” smaller than the first width “b”.

The first fin pattern 300p1 of the driving circuit chip package 120 should be inserted into the area corresponding to the first spacing s1 between the second patterns 200p of the display panel 100 and be in direct contact with the inclined side surfaces 200i facing each other of the adjacent second patterns 200p. Accordingly, a third width “c” in the first direction X of one first fin pattern 300p1 may be smaller than the first width “b” and greater than the second width “a”. In addition, a lower surface of the second fin pattern 300p2 of the driving circuit chip package 120 should be in contact with the first surface 200a as the upper surface of the second pattern 200p. Accordingly, the second width w3 in the first direction X of the second fin pattern 300p2 may be smaller than the first width w1 in the first direction X of the second pattern 200p.

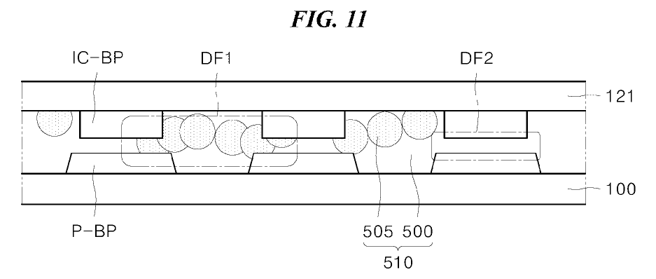

The display apparatus according to an embodiment of the present disclosure using the direct contact manner may transmit a signal more stably than the display apparatus using a coupling scheme using a conductive ball. Hereinafter, this will be described with reference to FIG. 11.

FIG. 11 is a diagram illustrating a display apparatus in which the first and second substrates 400 and 121 are coupled to each other using a conductive ball.

Referring to FIG. 11, an anisotropic conductive film 510 in which a plurality of conductive balls 505 are dispersed in the filling layer 500 is disposed between the second substrate 121 of the driving circuit chip package 120 and the first substrate 400 of the display panel 100. A first bump IC-BP as a contact and connection terminal is disposed on a lower surface of the second substrate 121 of the driving circuit chip package, and a second bump P-BP as a contact and connection terminal is disposed on an upper surface of the first substrate 400 of the display panel 100. The lower surface of the first bump IC-BP and the upper surface of the second bump P-BP may face each other. Different signals may be provided to adjacent first bumps IC-BP.

The first substrate 400 and the second substrate 121 may be coupled to each other by applying pressure thereto in a state in which the anisotropic conductive film 510 is placed therebetween. The plurality of conductive balls 505 may be in contact with the first bump IC-BP and the second bump P-BP in the vertical direction. Then, the first bump IC-BP and the second bump P-BP are electrically connected to each other via the conductive balls 505. That is, as the plurality of conductive balls 505 are disposed between the first bump IC-BP and the second bump P-BP, the contact scheme therebetween may be a point contact scheme.

Since the different signals are provided to the adjacent first bumps IC-BP, the conductive balls 505 dispersed in the horizontal direction should be electrically insulated from each other. However, the first bumps IC-BP may be spaced from each other by a fine pitch or the second bumps P-BP may be spaced from each other by a fine pitch, such that connection defects DF1 and DF2 may occur due to the conductive balls 505.

For example, when the conductive balls 505 are not uniformly distributed, the connection defects may occur. In an example, the conductive balls 505 may be disposed in the aggregated manner between the first bumps IC-BP or the second bumps P-BP arranged to be spaced apart from each other in the horizontal direction. As a result, the first bumps IC-BP or the second bumps P-BP arranged to be spaced apart from each other in the horizontal direction may be electrically connected to each other, such that the defect DF1 as a short-circuit defect may occur. Alternatively, the conductive balls 505 are not uniformly distributed, such that the conductive balls may not be disposed between the first bump IC-BP and the second bump P-BP overlapping each other the vertical direction. As a result, an open circuit defect DF2 in which the first bump IC-BP and the second bump P-BP do not electrically communicate with each other may occur.

In the coupling scheme using the anisotropic conductive film 510, it may be difficult to stably maintain the electrical connection between the display panel 100 and the driving circuit chip package 120 because the electrical connection therebetween is made using the conductive balls 505 non-uniformly dispersed in the filling layer. In addition, the conductive balls 505 are coupled to each other in a point contact manner, such that contact resistance therebetween may increase, and thus, a greater amount of power consumption may be consumed.

In this regard, in the display apparatus according to an embodiment of the present disclosure, the display panel 100 and the driving circuit chip package 120 may be electrically connected to each other in a manner in which the plurality of fourth patterns 300p of the driving circuit chip package 120 and the plurality of second patterns 200p of the display panel 100 are in direct surface and line contact with each other. Accordingly, the electrical connection therebetween may be stably maintained even when the conductive ball is not used. In addition, since the conductive ball is not applied, occurrence of the short circuit defect and the open circuit defect may be prevented. In addition, as the plurality of second patterns 200p and the plurality of fourth patterns 300p are in direct surface and line contact with each other, a contact and connection area between the patterns 200p and 300p may increase. As the contact and connection area increases, the contact resistance between the patterns 200p and 300p may be reduced, and thus the electrical conductivity therebetween may be improved. In addition, the signal path length may be shortened because the plurality of the second patterns 200p and the plurality of fourth patterns 300p are in direct contact with each other and electrically connected to each other. Accordingly, noise generation due to an increase in the signal path length may be prevented.

Furthermore, the display apparatus according to another embodiment of the present disclosure may include a structure capable of minimizing the influence of the alignment between the plurality of second patterns 200p and the plurality of fourth patterns 300p in the process of coupling the plurality of second patterns 200p and the plurality of fourth patterns 300p to each other. Hereinafter, this will be described with reference to the drawings.

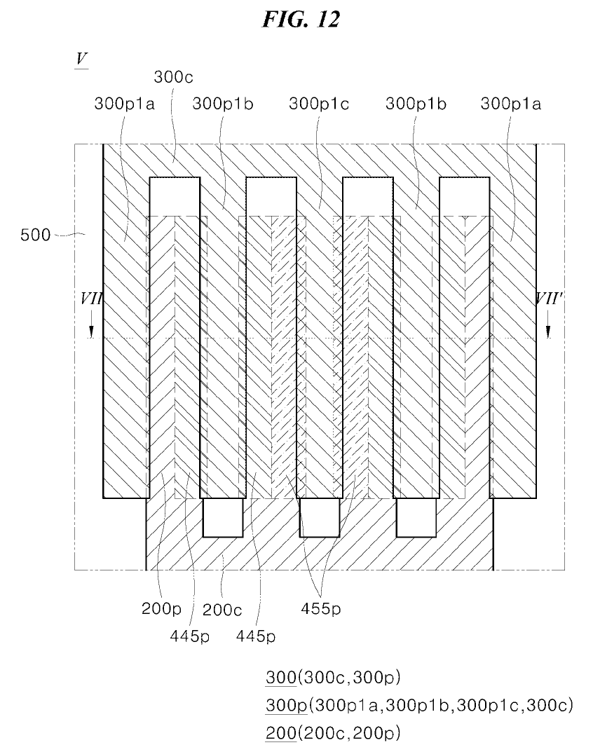

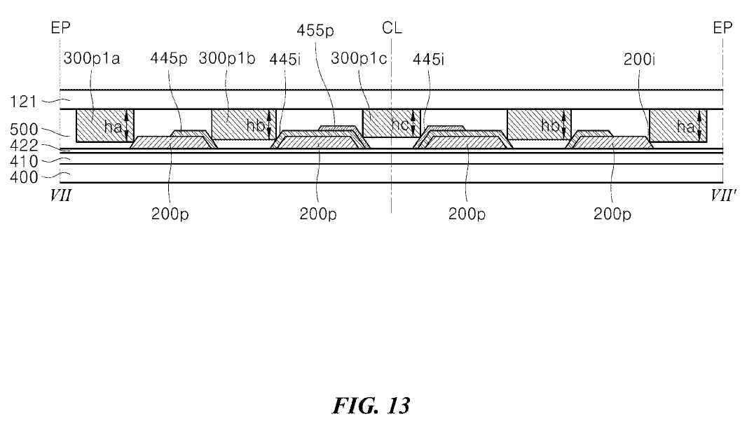

FIGS. 12 and 13 are diagrams illustrating a display apparatus according to another embodiment of the present disclosure. The same reference numerals in FIGS. 12 and 13 as those of FIGS. 7 and 8 may denote substantially the same components as those of FIGS. 7 and 8. Accordingly, redundant descriptions thereof will be omitted or briefly set forth.

Referring to FIGS. 12 and 13, the second pad 300 of the driving circuit chip package 120 and the first pad 200 of the display panel 100 may be disposed to overlap each other in vertical direction. The first pad 200 may include the first pad patterns 200c and 200p. In addition, a first stabilization patterns 445p and a second stabilization pattern 455p may be stacked on the first pad 200. The second pad 300 may include the second pad patterns 300c and 300p.

The first pad patterns 200c and 200p may include the first pattern 200c and the plurality of second patterns 200p. Each of the plurality of second patterns 200p may have a shape branching from the first pattern 200c and extending therefrom. For example, the first pad 200 may have a comb-like structure. The second patterns 200p may be arranged to be spaced apart from each other with a predetermined spacing in the first direction X.

Each of the first stabilization pattern 445p and the second stabilization pattern 455p may act as a structure capable of minimizing the influence of the alignment during the bonding process. Each of the first stabilization pattern 445p and the second stabilization pattern 455p may act as an auxiliary structure capable of maintaining the position. The first stabilization pattern 445p may be referred to as a first auxiliary structure, and the second stabilization pattern 455p may be referred to as a second auxiliary structure.

For example, all of the second patterns 200p may have the same thickness. In this case, the second pad patterns 300c and 300p to be coupled to the second patterns 200p may not be aligned therewith in the bonding process. For example, in the bonding process, a phenomenon in which the second pad patterns 300c and 300p are displaced in the left or right direction may occur. As a result, an alignment error in which the second pad patterns 300c and 300p are disposed at positions deviating from the reference alignment range may occur. When the alignment error occurs, the second pad patterns 300c and 300p may not be disposed at a position at which the second pad patterns 300c and 300p extend through the filling layer 500 so as to contact the second patterns 200p. As a result, a defect in which the second pad patterns 300c and 300p do not contact the first pad patterns 200c and 200p may occur, and thus a product defect may occur. Accordingly, according to an embodiment of the present disclosure, the auxiliary structure capable of maintaining the position of the second pad patterns 300c and 300p relative to the first pad patterns 200c and 200p so as not to deviate from the alignment range during the bonding process may be included.

The auxiliary structure allows the positions of the second pad patterns 300c and 300p not to deviate from the alignment range in the central area CL of the array of the plurality of second patterns 200p. The auxiliary structure may include the first stabilization pattern 445p and the second stabilization pattern 455p.

To this end, the first stabilization pattern 445p may be disposed on each of the plurality of second patterns 200p. The first stabilization pattern 445p may be disposed on a partial area of each of some of the plurality of second patterns 200. The plurality of second patterns 200p may be arranged to be spaced apart from each other in the direction toward each of both opposing end areas EP in the first direction X around the central area CL. The first stabilization pattern 445p may be disposed on each of the second patterns 200p disposed in the central area CL. The first stabilization pattern 445p may be disposed on the upper surface and both inclined side surfaces in the first direction of the second pattern 200p disposed in the central area CL. The first stabilization pattern 445p may be disposed on a partial area of the second pattern 200p disposed in each of both opposing end areas EP. More specifically, the first stabilization pattern 445p may be disposed on one inclined side surface and a portion of the upper surface of the second pattern 200p disposed in each of both opposing end areas EP. Accordingly, the first stabilization pattern 445p is not disposed on the other inclined side surface and a partial area of the upper surface the second pattern 200p disposed in each of both opposing end areas EP, so that the other inclined side surface and the partial area of the upper surface may be exposed.

A width in the first direction X of the first stabilization pattern 445p disposed on one inclined side surface and the partial area of the upper surface of the second pattern 200p may be a size of 1/2 of the overall width in the first direction X of the second pattern 200p. For example, when the overall width in the first direction X of the second pattern 200p is 3 micrometers (µm), the overall width in the first direction X of the first stabilization pattern 445p disposed on one inclined side surface and the partial area of the upper surface of the second pattern 200p may be 1.5 micrometers (µm).

The second stabilization pattern 455p may be disposed on the first stabilization pattern 445p disposed in the central area CL. The second stabilization pattern 455p may be stacked on one of both opposing areas in the first direction around a central vertical axis of the first stabilization pattern 445p. For example, the second stabilization pattern 455p may be disposed on one inclined side surface 445i and a half partial area of an upper surface of the first stabilization pattern 445p.

The width in the first direction X of the second stabilization pattern 455p disposed on one inclined side surface 445i and the half partial area of the upper surface of the first stabilization pattern 445p may be 1/2 of the overall width in the first direction X of the second pattern 200p. For example, when the overall width in the first direction X of the second pattern 200p is 3 micrometers (µm), the overall width in the first direction X of the second stabilization pattern 455p may be 1.5 micrometers (µm). In an example, the width in the first direction X of the second stabilization pattern 455p does not exceed 1/2 of the overall width in the first direction X of the second pattern 200p.

As the first stabilization pattern 445p and the second stabilization pattern 455p are disposed on the second pattern 200p in the central area CL, the central area CL may include a first portion in which both the first stabilization pattern 445p and the second stabilization pattern 455p are disposed on the second pattern 200p, and a second portion in which only the first stabilization pattern 445p is disposed thereon. The second portion in which only the first stabilization pattern 445p is disposed on the second pattern 200p and a third portion in which the surface of the second pattern 200p is exposed may be included in each of both opposing end areas EP. Accordingly, a stepwise structure in which a total thickness of the structure on the first substrate 400 increases step by step as the first substrate 400 extends from each of both opposing end areas EP toward the central area CL may be formed. That is, the thickness of the structure may be the largest in the first portion of the central area CL, and the thickness thereof may be the smallest in the third portion of each of both opposing end areas EP.

A conductive material may be included in each of the first stabilization pattern 445p and the second stabilization pattern 455p. For example, the first stabilization pattern 445p may be made of the same material as that of the second source electrode 445 of the display area DA and be formed in the same process as the process for forming the second source electrode 445 of the display area DA. For example, the second stabilization pattern 455p may be made of the same material as that of the pixel contact electrode 455 and be formed in the same process as the process for forming the pixel contact electrode 455. For example, the first stabilization pattern 445p or the second stabilization pattern 455p may have a single layer structure or a multilayer structure made of one of molybdenum (Mo), aluminum (Al), chromium (Cr), gold (Au), titanium (Ti), nickel (Ni), neodymium (Nd), and copper (Cu) or an alloy thereof. In an example, the first stabilization pattern 445p or the second stabilization pattern 455p may have a stacked structure of titanium layer/aluminum layer/titanium layer (Ti/Al/Ti).

The second pad patterns 300c and 300p of the driving circuit chip package 120 (see FIG. 6) may include the third pattern 300c and the plurality of fourth patterns 300p. The plurality of fourth patterns 300p may include a first fin pattern 300p1a, a second fin pattern 300p1b, and a third fin pattern 300p1c. The first fin pattern 300p1a may constitute one disposed in each of both opposing end areas EP among the plurality of fourth patterns 300p. The third fin pattern 300p1c may constitute one disposed in the central area CL among the plurality of fourth patterns 300p. The second fin pattern 300p1b may be disposed between the first fin pattern 300p1a and the third fin pattern 300p1c in the first direction X.

The first fin pattern 300p1a, the second fin pattern 300p1b, and the third fin pattern 300p1c may have different thicknesses. For example, among the plurality of fourth patterns 300p, the first fin pattern 300p1a constituting one disposed at each of both opposing end areas EP among the plurality of fourth patterns 300p may have a first thickness ha, and the third fin pattern 300p1c constituting one disposed at the central area CL among the plurality of fourth patterns 300p may have a third thickness hc. The second fin pattern 300p1b disposed between the first fin pattern 300p1a and the third fin pattern 300p1c in the first direction X may have a second thickness hb.

The third thickness hc of the third fin pattern 300p1c disposed in the central area CL may be the smallest, and the first thickness ha of the first fin pattern 300p1a disposed in each of both opposing end areas EP may be the greatest. The second thickness hb of the second fin pattern 300p1b may be greater than the third thickness hc of the third fin pattern 300p1c and smaller than the first thickness ha of the first fin pattern 300p1a. Accordingly, the thicknesses of the plurality of fourth patterns 300p decrease step by step as the plurality of fourth patterns 300p are sequentially arranged in the direction from each of both opposing end areas EP to the central area CL.

The first and/or second stabilization patterns are stacked on the plurality of second patterns 200p to form a stack. The stacks are arranged in the first direction X. The thicknesses of the stacks may increase step by step as the stacks are sequentially arranged in the direction from each of both opposing end areas EP toward the central area CL. The thicknesses of the plurality of fourth patterns 300p decreases step by step as the plurality of fourth patterns 300p are sequentially arranged in the direction from each of both opposing end areas EP to the central area CL. Each of the plurality of fourth patterns 300p may be inserted into a space defined between adjacent ones of the second patterns 200p. Accordingly, each of the plurality of fourth patterns 300p may be inserted into the space defined between adjacent ones of the second patterns 200p in a wedge shape.

The first fin pattern 300p1a of the fourth pattern 300p is disposed in each of both opposing end areas EP and has the greatest thickness ha. Accordingly, the pattern having the greatest thickness positioned at the outermost area may allow the coupled state between the second pattern and the fourth pattern positioned inwardly thereof to be maintained, such that the alignment between the second pattern and the fourth pattern may be maintained during the bonding process. Each corner of the first fin pattern 300p1a may extend through the filling layer 500 so as to be in contact with and electrically connected to the inclined side surface 200i of the second pattern 200p corresponding thereto. The third fin pattern 300p1c of the fourth pattern 300p is disposed in the central area CL and has the smallest thickness hc. A state in which the third fin pattern 300p1c is in contact with the respective inclined side surfaces 455i facing each other of the adjacent second stabilization patterns 455p may be maintained. Accordingly, the second stabilizing pattern 455p may allow the coupled state between the second pattern and the fourth pattern positioned outwardly thereof to be maintained, such that the alignment between the second pattern and the fourth pattern may be maintained during the bonding process. Each corner of the third fin pattern 300p1c may extend through the filling layer 500 so as to be in contact with and electrically connected to the inclined side surfaces 455i facing each other of the adjacent second stabilization patterns 455p.

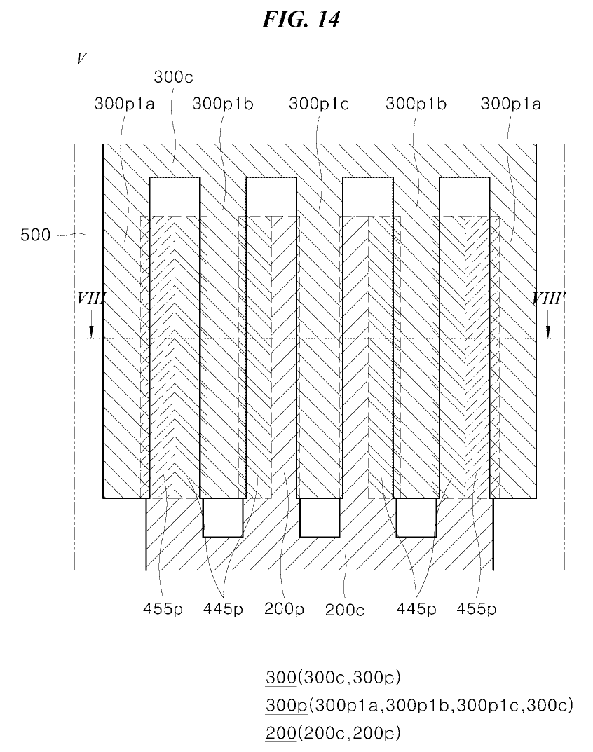

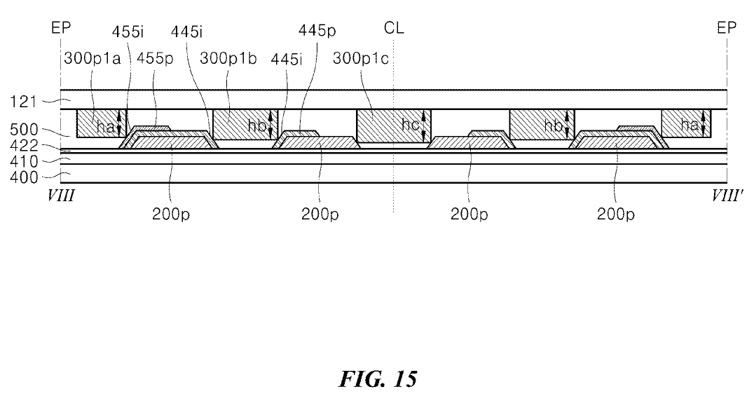

FIGS. 14 and 15 are diagrams illustrating a display apparatus according to still another embodiment of the present disclosure. FIGS. 14 and 15 are different from FIGS. 12 and 13 in terms of the thickness of each stack of each of the second patterns 200p and the first and/or second stabilization pattern and the thickness of each of the plurality of fourth patterns 300p, and the position where each of the first stabilization pattern 445p and the second stabilization pattern 455p is disposed. The same reference numerals in FIGS. 14 and 15 as those of FIGS. 12 and 13 may denote substantially the same components as those of FIGS. 12 and 13. Accordingly, redundant descriptions thereof will be omitted or briefly set forth.

Referring to FIGS. 14 and 15, the second pad 300 of the driving circuit chip package 120 and the first pad 200 of the display panel 100 may be disposed to overlap each other in vertical direction. The first pad 200 may include the first pad patterns 200c and 200p. In addition, the first stabilization pattern 445p and the second stabilization pattern 455p may be disposed on the first pad 200. The second pad 300 may include the second pad patterns 300c and 300p.

The first pad patterns 200c and 200p may include the first pattern 200c and the plurality of second patterns 200p. Each of the plurality of second patterns 200p may have a shape branching and extending from the first pattern 200c. For example, the first pad 200 may have a comb-like structure. The second patterns 200p may be arranged to be spaced apart from each other by a predetermined spacing in the first direction X.

Each of the first stabilization pattern 445p and the second stabilization pattern 455p may act as a structure capable of minimizing the influence of the alignment during the bonding process. Each of the first stabilization pattern 445p and the second stabilization pattern 455p may act as an auxiliary structure capable of maintaining the position. The first stabilization pattern 445p may be referred to as a first auxiliary structure, and the second stabilization pattern 455p may be referred to as a second auxiliary structure.

For example, all of the second patterns 200p may have the same thickness. In this case, the second pad patterns 300c and 300p to be coupled to the second patterns 200p may not be aligned therewith in the bonding process. For example, in the bonding process, a phenomenon in which the second pad patterns 300c and 300p are displaced in the left or right direction may occur. As a result, an alignment error in which the second pad patterns 300c and 300p are disposed at positions deviating from the reference alignment range may occur. When the alignment error occurs, the second pad patterns 300c and 300p may not be disposed at a position at which the second pad patterns 300c and 300p extend through the filling layer 500 so as to contact the second patterns 200p. As a result, a defect in which the second pad patterns 300c and 300p do not contact the first pad patterns 200c and 200p may occur, and thus a product defect may occur. Accordingly, according to an embodiment of the present disclosure, the auxiliary structure capable of maintaining the position of the second pad patterns 300c and 300p relative to the first pad patterns 200c and 200p so as not to deviate from the alignment range during the bonding process may be included.

The auxiliary structure allows the positions of the second pad patterns 300c and 300p not to deviate from the alignment range in the central area CL of the array of the plurality of second patterns 200P. The auxiliary structure may include the first stabilization pattern 445p and the second stabilization pattern 455p.

To this end, the first stabilization pattern 445p may be disposed on each of the plurality of second patterns 200p. The first stabilization pattern 445p may be disposed on a partial area of each of some of the plurality of second patterns 200. The plurality of second patterns 200p may be arranged to be spaced apart from each other in the direction toward each of both opposing end areas EP in the first direction X around the central area CL. The first stabilization pattern 445p may be disposed on each of the second patterns 200p disposed in the central area CL. The first stabilization pattern 445p may be disposed on the upper surface and both inclined side surfaces in the first direction of the second pattern 200p disposed in each of both opposing end areas EP.

The first stabilization pattern 445p may be disposed on a partial area of the second pattern 200p disposed in the central area CL. More specifically, the first stabilization pattern 445p may be disposed on one inclined side surface and a portion of the upper surface of the second pattern 200p disposed in the central area CL. Accordingly, the first stabilization pattern 445p is not disposed on the other inclined side surface and a partial area of the upper surface the second pattern 200p disposed in the central area, so that the other inclined side surface and the partial area of the upper surface may be exposed.

A width in the first direction X of the first stabilization pattern 445p disposed on one inclined side surface and the partial area of the upper surface of the second pattern 200p may be a size of 1/2 of the overall width in the first direction X of the second pattern 200p. For example, when the overall width in the first direction X of the second pattern 200p is 3 micrometers (µm), the overall width in the first direction X of the first stabilization pattern 445p disposed on one inclined side surface and the partial area of the upper surface of the second pattern 200p may be 1.5 micrometers (µm).

As the first stabilization pattern 445p and the second stabilization pattern 455p are disposed on the second pattern 200p in the central area CL, each of both opposing end areas EP may include a first portion in which both the first stabilization pattern 445p and the second stabilization pattern 455p are disposed on the second pattern 200p, and a second portion in which only the first stabilization pattern 445p is disposed thereon. The second portion in which only the first stabilization pattern 445p is disposed on the second pattern 200p and a third portion in which the surface of the second pattern 200p is exposed may be included in the central area CL. Accordingly, a stepwise structure in which a total thickness of the structure on the first substrate 400 decreases step by step as the first substrate 400 extends from each of both opposing end areas EP toward the central area CL may be formed. That is, the thickness of the structure may be the smallest in the first portion of the central area CL, and the thickness thereof may be the largest in the third portion of the end area EP.

A conductive material may be included in each of the first stabilization pattern 445p and the second stabilization pattern 455p. For example, the first stabilization pattern 445p may be made of the same material as that of the second source electrode 445 of the display area DA and be formed in the same process as the process for forming the second source electrode 445 of the display area DA. For example, the second stabilization pattern 455p may be made of the same material as that of the pixel contact electrode 455 and be formed in the same process as the process for forming the pixel contact electrode 455. For example, the first stabilization pattern 445p or the second stabilization pattern 455p may have a single layer structure or a multilayer structure made of one of molybdenum (Mo), aluminum (Al), chromium (Cr), gold (Au), titanium (Ti), nickel (Ni), neodymium (Nd), and copper (Cu) or an alloy thereof. In an example, the first stabilization pattern 445p or the second stabilization pattern 455p may have a stacked structure of titanium layer/aluminum layer/titanium layer (Ti/Al/Ti).

The second pad patterns 300c and 300p of the driving circuit chip package 120 (see FIG. 6) may include the third pattern 300c and the plurality of fourth patterns 300p. The plurality of fourth patterns 300p may include a first fin pattern 300p1a, a second fin pattern 300p1b, and a third fin pattern 300p1c. The first fin pattern 300p1a may constitute one disposed in each of both opposing end areas EP among the plurality of fourth patterns 300p. The third fin pattern 300p1c may constitute one disposed in the central area CL among the plurality of fourth patterns 300p. The second fin pattern 300p1b may be disposed between the first fin pattern 300p1a and the third fin pattern 300p1c in the first direction X.

The first fin pattern 300p1a, the second fin pattern 300p1b, and the third fin pattern 300p1c may have different thicknesses. For example, among the plurality of fourth patterns 300p, the first fin pattern 300p1a constituting one disposed in each of both opposing end areas EP among the plurality of fourth patterns 300p may have a first thickness ha, and the third fin pattern 300p1c constituting one disposed at the central area CL among the plurality of fourth patterns 300p may have a third thickness hc. The second fin pattern 300p1b disposed between the first fin pattern 300p1a and the third fin pattern 300p1c in the first direction X may have a second thickness hb.

The third thickness hc of the third fin pattern 300p1c disposed in the central area CL may be the largest, and the first thickness ha of the first fin pattern 300p1a disposed in each of both opposing end areas EP may be the smallest. The second thickness hb of the second fin pattern 300p1b may be smaller than the third thickness hc of the third fin pattern 300p1c and larger than the first thickness ha of the first fin pattern 300p1a. Accordingly, the thicknesses of the plurality of fourth patterns 300p increases step by step as the plurality of fourth patterns 300p are sequentially arranged in the direction from each of both opposing end areas EP to the central area CL.

The first and/or second stabilization patterns are stacked on the plurality of second patterns 200p to form a stack. The stacks are arranged in the first direction X. The thicknesses of the stacks may decrease step by step as the stacks are sequentially arranged in the direction from each of both opposing end areas EP toward the central area CL. The thicknesses of the plurality of fourth patterns 300p increase step by step as the plurality of fourth patterns 300p are sequentially arranged in the direction from each of both opposing end areas EP to the central area CL. Each of the plurality of fourth patterns 300p may be inserted into a space defined between adjacent ones of the second patterns 200p. Accordingly, each of the plurality of fourth patterns 300p may be inserted into the space defined between adjacent ones of the second patterns 200p in a wedge shape.

The third fin pattern 300p1c of the fourth pattern 300p is disposed in the central area CL and has the largest thickness hc. A state in which the third fin pattern 300p1c is in contact with the respective inclined side surfaces facing each other of the adjacent second patterns 200P may be maintained. Accordingly, the coupled state between the second pattern and the fourth pattern may be maintained in the central area CL, such that the alignment between the second pattern and the fourth pattern may be maintained during the bonding process. Each corner of the third fin pattern 300p1c may extend through the filling layer 500 so as to be in contact with and electrically connected to each of the respective inclined side surfaces facing each other of the adjacent second patterns 200P.

The first fin pattern 300p1a of the fourth pattern 300p is disposed in each of both opposing end areas EP. Accordingly, the pattern positioned at the outermost area may allow the coupled state between the second pattern and the fourth pattern positioned inwardly thereof to be maintained, such that the alignment between the second pattern and the fourth pattern may be maintained during the bonding process. A state in which the first fin pattern 300p1a is in contact with the inclined side surface 455i of the second stabilization pattern 455p may be maintained. Accordingly, the second stabilizing pattern 455p may allow the coupled state between the second pattern and the fourth pattern positioned outwardly thereof to be maintained, such that the alignment between the second pattern and the fourth pattern may be maintained during the bonding process. The corner of the first fin pattern 300p1a may extend through the filling layer 500 so as to be in contact with and electrically connected to the inclined side surface 455i of the second stabilization pattern 455p.

In one embodiment, when the second pattern 200p including a metal material is exposed to moisture, corrosion or electrolytic corrosion may occur, resulting in a defect. Accordingly, the display apparatus according to still another embodiment of the present disclosure may include a structure capable of preventing the second pattern 200p from being exposed to moisture.

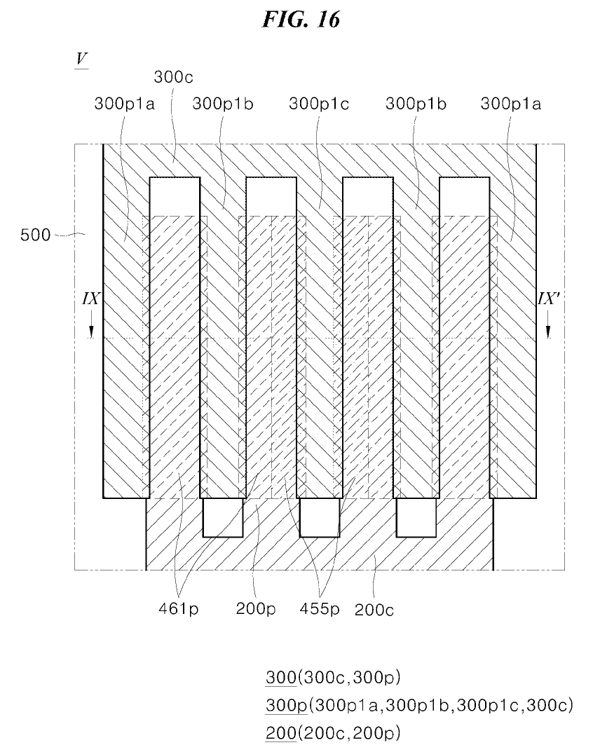

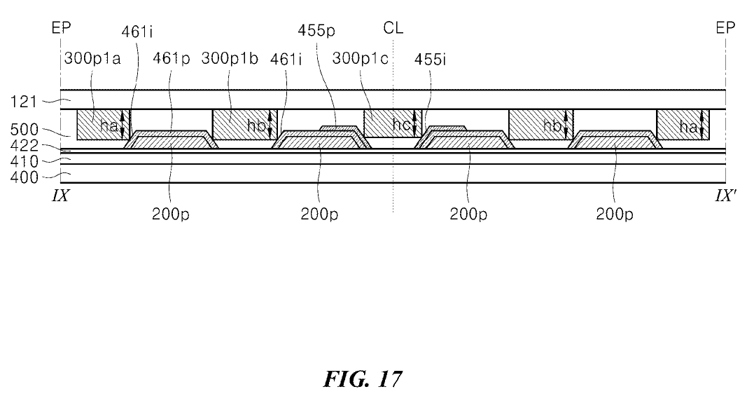

FIGS. 16 and 17 are diagrams illustrating a display apparatus according to still yet another embodiment of the present disclosure. The same reference numerals in FIGS. 16 and 17 as those of FIGS. 12 and 13 may denote substantially the same components as those of FIGS. 12 and 13. Accordingly, redundant descriptions thereof will be omitted or briefly set forth.

Referring to FIGS. 16 and 17, the second pad 300 of the driving circuit chip package 120 and the first pad 200 of the display panel 100 may be disposed to overlap each other in vertical direction. The first pad 200 may include the first pad patterns 200c and 200p. The second pad 300 may include the second pad patterns 300c and 300p.

The first pad patterns 200c and 200p may include the first pattern 200c and the plurality of second patterns 200p. The plurality of second patterns 200p may have a shape branching and extending from the first pattern 200c. For example, the first pad 200 may have a comb-like structure. The second patterns 200p may be spaced apart from each other by a predetermined spacing. For example, the plurality of second patterns 200p may be arranged to be spaced apart from each other in the direction toward each of both opposing end areas EP around the central area CL.

A cover layer 461p may be disposed on each of the plurality of second patterns 200p. The cover layer 461p may entirely cover the exposed surface of each of the second patterns 200p. For example, the cover layer 461p may cover the upper surface and both inclined side surfaces in the first direction of the second pattern 200p. The cover layer 461p may be made of the same material as that of the first electrode 461 of the display area DA and be formed in the same process as the process for forming the first electrode 461 of the display area DA. Accordingly, since an additional process is not required, the process may be simplified and production energy may be reduced.

The cover layer 461p includes a material capable of preventing moisture penetration, thereby preventing the moisture from penetrating into the second pattern 200p. Accordingly, the occurrence of a corrosion defect or an electrolytic corrosion defect of the second pattern 200p may be prevented. This may prevent the occurrence of an operation failure of the display apparatus, thereby improving the reliability of the product.

An auxiliary structure for preventing the misalignment between the second and fourth patterns may be disposed on the cover layer 461p. The auxiliary structure may be disposed on the plurality of second patterns 200P disposed on at least the central area CL to maintain the positions of the second pad patterns 300c and 300p so as not to be deviate from the alignment range. The auxiliary structure may include the second stabilization pattern 455p. In an embodiment of the present disclosure, an example in which the second stabilization pattern 455p acts as an auxiliary structure is described. However, the present disclosure is not limited thereto. For example, the auxiliary structure may be embodied as the first stabilization pattern 445p (see FIG. 13).

The second stabilization pattern 455p may be disposed on each of some patterns among the plurality of second patterns 200p. For example, the second stabilization pattern 455p may be disposed on the second pattern 200p disposed adjacent to a vertical central axis of the central area CL. The second stabilizing pattern 455p may be stacked on one of both opposing areas in the first direction of the second pattern 200p. For example, the second stabilizing pattern 455p may be disposed on each of the respective inclined side surfaces 461i facing each other of the cover layers 461p respectively disposed on the second patterns 200p adjacent to each other in the central area CL. The second stabilization pattern 455p may extend on and along one inclined side surface 461i of the cover layer 461p and on and along a partial area of the upper surface of the cover layer 461p. Accordingly, the other inclined side surface and the partial area of the upper surface of the cover layer 461p may be exposed. As a result, a stepwise structure in which a total thickness of the structure on the first substrate 400 increases step by step as the first substrate 400 extends from each of both opposing end areas EP toward the central area CL may be formed.

A conductive material may be included in the second stabilization pattern 455p. For example, the second stabilization pattern 455p may be made of the same material as that of the pixel contact electrode 455 and be formed in the same process as the pixel contact electrode 455. In an example, the second stabilizing pattern 455p may have a stacked structure of titanium layer/aluminum layer/titanium layer (Ti/Al/Ti).

The fourth patterns 300p of the second pad patterns 300c and 300p may include the first fin pattern 300p1a, the second fin pattern 300p1b, and the third fin pattern 300p1c. The first fin patterns 300p1a may be respectively disposed in both opposing end areas EP. The third fin pattern 300p1c may be disposed in the central area CL. The second fin pattern 300p1b may be disposed between the first fin pattern 300p1a and the third fin pattern 300p1c in the first direction X.

The first fin pattern 300p1a, the second fin pattern 300p1b, and the third fin pattern 300p1c may have different thicknesses in a corresponding manner to the thicknesses of the stacks, each stack including the second patterns 200p and the cover layer and/or the second stabilization pattern. For example, the first fin pattern 300p1a disposed in each of both opposing end areas EP may have a first thickness ha, and the third fin pattern 300p1c disposed in the central area CL may have a third thickness hc. The second fin pattern 300p1b disposed between the first fin pattern 300p1a and the third fin pattern 300p1c may have a second thickness hb.

The third thickness ha of the third fin pattern 300p1c disposed in the central area CL may be the smallest thickness hc, and the first fin pattern 300p1a disposed in each of both opposing end areas EP may have the largest thickness ha. The second thickness hb of the second fin pattern 300p1b may be smaller than the first thickness ha of the first fin pattern 300p1a and greater than the third thickness hc of the third fin pattern 300p1c. Accordingly, the thicknesses of the plurality of fourth patterns 300p decreases step by step as the plurality of fourth patterns 300p are sequentially arranged in the direction from each of both opposing end areas EP to the central area CL.

The third fin pattern p1c disposed in the central area CL may contact the cover layer 461p and the second stabilization pattern 455p disposed on the second pattern 200p and maintaining the position of the second pattern 200p, thereby preventing the misalignment between the second and fourth patterns during the bonding process. The third fin pattern 300p1c may be in contact with the inclined side surface 455i of the second stabilization pattern 455p and may be electrically connected to the second pattern 200p.

The first fin pattern 300p1a may have the largest thickness ha and may maintain the coupled state between the second and fourth patterns in each of both opposing end areas EP to prevent the misalignment therebetween. The corner of the first fin pattern 300p1a may extend through the filling layer 500 so as to contact the inclined side surface 461i of the cover layer 461p. Thus, the first fin pattern 300p1a may be electrically connected to the second pattern 200p.

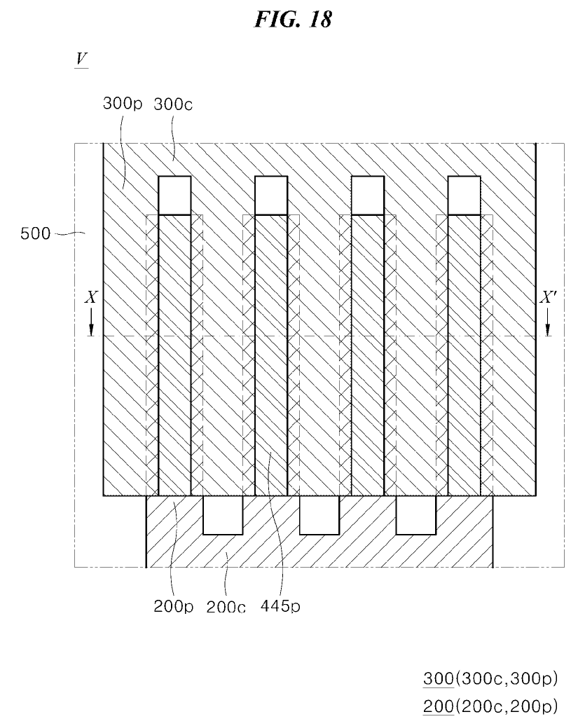

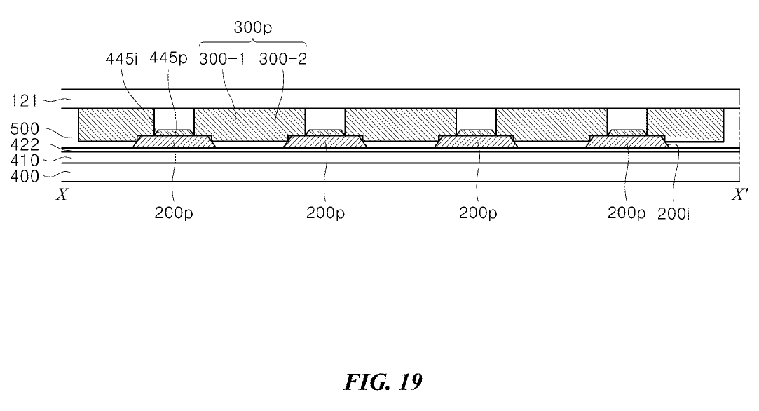

FIGS. 18 and 19 are diagrams illustrating a display apparatus according to still yet another embodiment of the present disclosure. The same reference numerals in FIGS. 18 and 19 as those of FIGS. 12 and 13 may denote substantially the same components as those of FIGS. 12 and 13. Accordingly, redundant descriptions thereof will be omitted or briefly set forth.

Referring to FIGS. 18 and 19, the second pad 300 of the driving circuit chip package 120 and the first pad 200 of the display panel 100 may be disposed to overlap each other in vertical direction. The first pad 200 may include the first pad patterns 200c and 200p. The second pad 300 may include the second pad patterns 300c and 300p.

The first pad patterns 200c and 200p may include the first pattern 200c and the plurality of second patterns 200p. The second patterns 200p may be spaced apart from each other by a predetermined spacing. The second pattern 200p may have a width in the first direction X of an upper surface thereof smaller than a width in the first direction X of a bottom surface thereof. Accordingly, the inclined side surface may be defined between the upper surface and the bottom surface thereof. An auxiliary structure for preventing the misalignment may be disposed on the upper surface of the second pattern 200p. The auxiliary structure may include the first stabilization pattern 445p. The width in the first direction X of the first stabilizing pattern 445p may be smaller than the width in the first direction X of the second pattern 200p. Accordingly, a portion of the upper surface of the second pattern 200p may not be covered with the first stabilization pattern 445p so as to be exposed.

In an embodiment of the present disclosure, an example in which the first stabilization pattern 445p acts as the auxiliary structure is described. However, embodiments of the present disclosure are not limited thereto. For example, the auxiliary structure may be embodied as the second stabilization pattern 455p (see FIG. 13). In addition, the auxiliary structure may be embodied as a cover layer 461 (see FIG. 17).

A conductive material may be included in the first stabilization pattern 445p. For example, in the first stabilization pattern 445p, the first stabilization pattern 445p may be made of the same material as that of the second source electrode 445 of the display area DA and be formed in the same process as the process for forming the second source electrode 445 of the display area DA. In an example, the second stabilization pattern 455p may have a stack structure of titanium layer/aluminum layer/titanium layer (Ti/Al/Ti).

Each of the plurality of fourth patterns 300p of the second pad patterns 300c and 300p may include a body 300-1 and a protrusion 300-2. The body 300-1 and the protrusion 300-2 of each of the plurality of fourth patterns 300p may be integrally formed with each other. A width in the first direction X of the protrusion 300-2 may be smaller than a width in the first direction X of the body 300-1. The protrusion 300-2 may vertically overlap at least a central area of the body 300-1. Accordingly, the width in the first direction of the protrusion is smaller than a width in the first direction of the body such that each right-angled surface is defined between each of both opposing side surfaces in the first direction of the body 300-1 and a lower surface of the protrusion 300-2. In this case, the right-angled surface may define a step between the protruding portion 300-2 and the body 300-1. The fourth pattern 300p including the body 300-1 and the protrusion 300-2 may also be referred to as a wedge pattern.

The fourth pattern 300p may be inserted into a space between adjacent second patterns 200p. In this regard, the right-angled surface defined between the lower surface of the protrusion 300-2 and the side surface of the body 300-1 of the fourth pattern 300p may be in contact with the upper surface of the second pattern 200p and the inclined side surface 200i thereof. A horizontal portion of the right-angled surface may be in contact with the upper surface of the second pattern 200p while a vertical portion of the right-angled surface may be in contact with the inclined side surface thereof. For example, a portion of the lower surface of the body 300-1 of the fourth pattern 300p may be disposed to contact a portion of the upper surface of the second pattern 200p.

In addition, the protrusion 300-2 may extend through the filling layer 500 such that each of both opposing corners in the first direction X of the protrusion 300-2 is in surface contact with each of both opposing inclined side surfaces 200i in the first direction of the second pattern 200p. As a result, the fourth pattern 300p and the second pattern 200p may be electrically connected to each other in the surface and/or line contact manner with each other. In addition, a portion of the upper surface of the second pattern 200p and a portion of the lower surface of the body 300-1 of the fourth pattern 300p are in contact with each other, such that the contact and connection area therebetween may be increased. Therefore, the contact resistance between the second pattern 200p and the fourth pattern 300p is reduced, such that the electrical conductivity therebetween may be improved.

In addition, the first stabilization pattern 445p disposed on the upper surface of the second pattern 200p may minimize the influence of the misalignment during the bonding process. For example, the first stabilization pattern 445p may maintain the position of the fourth pattern 300p so as not to deviate from the alignment range during the bonding process.

According to embodiments of the present disclosure, the driving circuit chip package and the display panel may be electrically connected to each other while being coupled to each other in a manner in which the respective pads thereof are in surface and/or line contact with each other. Accordingly, the conductive ball may be omitted during the bonding process, thereby preventing the short circuit defect and the open circuit defect from occurring. Accordingly, the electrical connection between the display panel and the driving circuit chip may be stably realized, and thus the defect rate of the display apparatus may be reduced. As a result, the production energy required for additional production of the display apparatus may be reduced, such that there is an effect that greenhouse gas emission may be reduced.

In addition, as the pads of the driving circuit chip package and the display panel are coupled to each other in a manner in which the pads are in direct surface/line contact with each other, the contact and connection area therebetween may increase. Accordingly, the contact resistance therebetween may be lowered such that the electrical conductivity therebetween may be improved.

In addition, since the conductive ball may be omitted, a design margin for placing the conductive ball may be removed, and thus the pads may be arranged so as to be spaced from each other by at a finer pitch. Accordingly, the area size of each of the pad areas arranged in the same area may be reduced. Therefore, the pads may be arranged more densely per unit area. Accordingly, there is an effect of implementing a high-resolution display apparatus.

In addition, in the display apparatus according to the present disclosure, each structure constructed to minimize the influence of misalignment during the bonding process may be disposed on each of the driving circuit chip package and the display panel. Accordingly, the occurrence of the alignment error in which each of the pads of the driving circuit chip package and the display panel is disposed at a position deviating from the reference alignment range may be prevented, thereby improving the reliability of the product.

The display apparatus according to various aspects and embodiments of the present disclosure may be described as follows.

One aspect of the present disclosure provides a display apparatus comprising: a first substrate including a display area and a non-display area disposed outside the display area; a first pad area disposed in the non-display area of the first substrate; a first pad disposed on an upper surface of the first pad area and including a first pattern and a plurality of second patterns, wherein the plurality of second patterns are arranged to be spaced from each other by a first spacing; a second substrate disposed on top of the first substrate and including a second pad area; and a second pad disposed on a lower surface of the second pad area and including a third pattern and a plurality of fourth patterns, wherein the plurality of fourth patterns are arranged to be spaced from each other by a second spacing, wherein each of the fourth patterns is disposed in the first spacing and contacts a side surface of each of the second patterns.

In accordance with some embodiments of the present disclosure, the first pattern extends in a first direction of the first substrate, wherein the plurality of second patterns are arranged in the first direction, and each of the plurality of second patterns is branched from the first pattern and extends in a second direction intersecting the first direction.

In accordance with some embodiments of the present disclosure, the third pattern extends in a first direction of the second substrate, wherein the plurality of fourth patterns are arranged in the first direction, and each of the plurality of fourth patterns is branched from the third pattern and extends in a second direction intersecting the first direction.

In accordance with some embodiments of the present disclosure, respective first widths in a first direction of the plurality of second patterns are equal to each other.

In accordance with some embodiments of the present disclosure, each of the plurality of fourth patterns includes a first fin pattern and a second fin pattern, wherein the first and second fin patterns of the plurality of fourth patterns are arranged alternately with each other and are spaced from each other in a first direction, wherein the first fin patterns are arranged to be spaced from each other by the second spacing, wherein a second fin pattern is disposed between adjacent first fin patterns, wherein the first fin pattern constitutes each of both opposing ends in the first direction of the second pad, wherein the first fin pattern and the second fin pattern are branched from the third pattern.

In accordance with some embodiments of the present disclosure, a first width of the first fin pattern and a second width of the second fin pattern are different from each other.

In accordance with some embodiments of the present disclosure, a first width of the first fin pattern is greater than a second width of the second fin pattern.

In accordance with some embodiments of the present disclosure, a vertical length of the second fin pattern is smaller than a vertical length of the first fin pattern, and wherein one surface of the second fin pattern is in contact with an upper surface of the second pattern.

In accordance with some embodiments of the present disclosure, the display apparatus further comprises a filling layer disposed between the first substrate and the second substrate, wherein each of the plurality of fourth patterns extends through the filling layer so as to contact a side surface of the second pattern.

In accordance with some embodiments of the present disclosure, the filling layer is made of an insulating material free of a conductive material.

In accordance with some embodiments of the present disclosure, the plurality of second pad patterns are arranged to be spaced apart from each other in a direction from a central area of the first substrate to each of both opposing end areas in a first direction thereof, wherein the display apparatus further comprises: a first auxiliary structure covering an upper surface and both opposing side surfaces in the first direction of the second pattern disposed on the central area, and covering a partial area of an upper surface and one of both opposing side surfaces in the first direction of the second pattern disposed on each of both opposing end areas; and a second auxiliary structure disposed on one of both opposing inclined side surfaces in the first direction of the first auxiliary structure on the central area and a partial area of an upper surface of the first auxiliary structure on the central area.

In accordance with some embodiments of the present disclosure, a width in the first direction of the second auxiliary structure is smaller than 1/2 of a width in the first direction of the second pattern.

In accordance with some embodiments of the present disclosure, the plurality of fourth patterns includes a first fin pattern, a second fin pattern, and a third fin pattern having different thicknesses, wherein a corner of the third fin pattern contacts a side surface of the second auxiliary structure, wherein a corner of the second fin pattern contacts a side surface of the first auxiliary structure, wherein a corner of the first fin pattern contacts a side surface of the second pattern.

In accordance with some embodiments of the present disclosure, wherein a thickness of the first fin pattern is greatest, and a thickness of the third fin pattern is smallest.

In accordance with some embodiments of the present disclosure, wherein the plurality of second patterns are arranged to be spaced apart from each other toward a central area and toward both opposing end areas, wherein the display apparatus further comprises: a first auxiliary structure covering an upper surface and both side surfaces of the second pattern disposed on each of the opposing end areas, and a second auxiliary structure disposed on an outer inclined surface and partial area of an upper surface of the first auxiliary structure.

In accordance with some embodiments of the present disclosure, the plurality of fourth patterns include a first fin pattern, a second fin pattern, and a third fin pattern having different thicknesses, wherein a corner of the first fin pattern contacts a side surface of second auxiliary structure, wherein a corner of the second fin pattern contacts a side surface of the first auxiliary structure, wherein a corner of the third fin pattern contacts a side surface of the second pattern.

In accordance with some embodiments of the present disclosure, a thickness of the third fin pattern is greatest, and a thickness of the first fin pattern is smallest.

In accordance with some embodiments of the present disclosure, the plurality of second pad patterns are arranged to be spaced apart from each other toward a central area and toward both opposing end areas, wherein the display apparatus further comprises: a cover layer covering an upper surface and both inclined side surfaces of each of the second patterns; and an auxiliary structure disposed on one inclined side surface and a partial area of an upper surface of the cover layer covering the second pattern disposed on the central area.

In accordance with some embodiments of the present disclosure, the display apparatus further comprises an auxiliary structure disposed on an upper surface of each of the plurality of second patterns arranged in a first direction, wherein a width of the auxiliary structure is smaller than a width of an upper surface of the second pattern.

In accordance with some embodiments of the present disclosure, each of the plurality of fourth patterns includes: a body; a protrusion protruding from the body into the area corresponding to the first spacing, and a right-angled surface defined between a side surface of the body and a lower surface of the protrusion, wherein the right-angled surface contacts an upper surface and an inclined side surface of the second pattern.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A display apparatus comprising:
a first substrate including a display area and a non-display area disposed outside the display area;
a first pad area disposed in the non-display area of the first substrate;
a first pad disposed on an upper surface of the first pad area and including a first pattern and a plurality of second patterns, wherein the plurality of second patterns are arranged to be spaced from each other by a first spacing;
a second substrate disposed on top of the first substrate and including a second pad area; and
a second pad disposed on a lower surface of the second pad area and including a third pattern and a plurality of fourth patterns, wherein the plurality of fourth patterns are arranged to be spaced from each other by a second spacing,
wherein each of the fourth patterns is disposed in the first spacing and contacts a side surface of each of the second patterns.

2. The display apparatus of claim 1, wherein the first pattern extends in a first direction of the first substrate, and
wherein the plurality of second patterns are arranged in the first direction, and each of the plurality of second patterns is branched from the first pattern and extends in a second direction intersecting the first direction.

3. The display apparatus of claim 1, wherein the third pattern extends in a first direction of the second substrate, and
wherein the plurality of fourth patterns are arranged in the first direction, and each of the plurality of fourth patterns is branched from the third pattern and extends in a second direction intersecting the first direction.

4. The display apparatus of claim 1, wherein respective first widths in a first direction of the plurality of second patterns are equal to each other.

5. The display apparatus of claim 1, wherein each of the plurality of fourth patterns includes a first fin pattern and a second fin pattern,
wherein the first and second fin patterns of the plurality of fourth patterns are arranged alternately with each other and are spaced from each other in a first direction,
wherein the first fin patterns are arranged to be spaced from each other by the second spacing,
wherein a second fin pattern is disposed between adjacent first fin patterns,
wherein the first fin pattern constitutes each of both opposing ends in the first direction of the second pad, and
wherein the first fin pattern and the second fin pattern are branched from the third pattern.

6. The display apparatus of claim 5, wherein a first width of the first fin pattern and a second width of the second fin pattern are different from each other.

7. The display apparatus of claim 5, wherein a first width of the first fin pattern is greater than a second width of the second fin pattern.

8. The display apparatus of claim 5, wherein a vertical length of the second fin pattern is smaller than a vertical length of the first fin pattern, and
wherein one surface of the second fin pattern is in contact with an upper surface of the second pattern.

9. The display apparatus of claim 1, wherein the display apparatus further comprises a filling layer disposed between the first substrate and the second substrate, and
wherein each of the plurality of fourth patterns extends through the filling layer so as to contact a side surface of the second pattern.

10. The display apparatus of claim 9, wherein the filling layer is made of an insulating material free of a conductive material.

11. The display apparatus of claim 1, wherein the plurality of second patterns are arranged to be spaced apart from each other in a direction from a central area of the first substrate to each of both opposing end areas in a first direction thereof,
wherein the display apparatus further comprises:
a first auxiliary structure covering an upper surface and both opposing side surfaces in the first direction of the second pattern disposed on the central area, and covering a partial area of an upper surface and one of both opposing side surfaces in the first direction of the second pattern disposed on each of both opposing end areas; and
a second auxiliary structure disposed on one of both opposing inclined side surfaces in the first direction of the first auxiliary structure on the central area and a partial area of an upper surface of the first auxiliary structure on the central area.

12. The display apparatus of claim 11, wherein a width in the first direction of the second auxiliary structure is smaller than 1/2 of a width in the first direction of the second pattern.

13. The display apparatus of claim 11, wherein the plurality of fourth patterns includes a first fin pattern, a second fin pattern, and a third fin pattern having different thicknesses,
wherein a corner of the third fin pattern contacts a side surface of the second auxiliary structure,
wherein a corner of the second fin pattern contacts a side surface of the first auxiliary structure, and
wherein a corner of the first fin pattern contacts a side surface of the second pattern.

14. The display apparatus of claim 13, wherein a thickness of the first fin pattern is greatest, and a thickness of the third fin pattern is smallest.

15. The display apparatus of claim 1, wherein the plurality of second patterns are arranged to be spaced apart from each other toward a central area and toward both opposing end areas,
wherein the display apparatus further comprises:
a first auxiliary structure covering an upper surface and both side surfaces of the second pattern disposed on each of the opposing end areas, and
a second auxiliary structure disposed on an outer inclined surface and partial area of an upper surface of the first auxiliary structure.

16. The display apparatus of claim 15, wherein the plurality of fourth patterns include a first fin pattern, a second fin pattern, and a third fin pattern having different thicknesses,
wherein a corner of the first fin pattern contacts a side surface of second auxiliary structure,
wherein a corner of the second fin pattern contacts a side surface of the first auxiliary structure, and
wherein a corner of the third fin pattern contacts a side surface of the second pattern.

17. The display apparatus of claim 16, wherein a thickness of the third fin pattern is greatest, and a thickness of the first fin pattern is smallest.

18. The display apparatus of claim 1, wherein the plurality of second patterns are arranged to be spaced apart from each other toward a central area and toward both opposing end areas,
wherein the display apparatus further comprises:
a cover layer covering an upper surface and both inclined side surfaces of each of the second patterns; and
an auxiliary structure disposed on one inclined side surface and a partial area of an upper surface of the cover layer covering the second pattern disposed on the central area.

19. The display apparatus of claim 1, wherein the display apparatus further comprises an auxiliary structure disposed on an upper surface of each of the plurality of second patterns arranged in a first direction, and
wherein a width of the auxiliary structure is smaller than a width of an upper surface of the second pattern.

20. The display apparatus of claim 19, wherein each of the plurality of fourth patterns includes:
a body;
a protrusion protruding from the body into the area corresponding to the first spacing, and
a right-angled surface defined between a side surface of the body and a lower surface of the protrusion,
wherein the right-angled surface contacts an upper surface and an inclined side surface of the second pattern.
